(19) United States
(12) Patent Application Publication
(10) Pub. No.: US 2025/0006522 A1
(43) Pub. Date: Jan. 2, 2025

(54) SUBSTRATE TREATING APPARATUS

(71) Applicant: SCREEN Holdings Co., Ltd., Kyoto (JP)

(72) Inventors: Hiroaki ISHII, Kyoto-shi, Kyoto (JP); Junichi ISHII, Kyoto-shi, Kyoto (JP)

(21) Appl. No.: 18/709,752

(22) PCT Filed: Oct. 26, 2022
(86) PCT No.: PCT/JP2022/039935

§ 371 Date: May 13, 2024

(30) Foreign Application Priority Data
Nov. 17, 2021 (JP) 2021-187153

(51) Int. Cl. H01L 21/67; B24B 37/015

(52) U.S. Cl. CPC H01L 21/67219; B24B 37/015

(57) ABSTRACT

In a substrate treating apparatus, an indexer block, a polishing block, a coating block, and an interface block are arranged horizontally and linearly in this order. The coating block includes a coating unit PR-configured to coat a front face of a substrate with a resist. The polishing unit includes a polishing unit configured to polish a back face of the substrate. The polishing unit includes a holding rotator configured to rotate the substrate while holding the substrate in a horizontal posture, a heating member configured to heat the substrate, and a polisher having a resin body where abrasive grains are distributed and configured to polish the back face of the substrate in a chemo-mechanical grinding manner by contacting against the back face of the substrate that is rotated while being heated.

### TECHNICAL FIELD

The present invention relates to a substrate treating apparatus configured to polish a back face of a substrate. Examples of substrates include semiconductor substrates, substrates for flat panel displays (FPDs), glass substrates for photomasks, substrates for optical disks, substrates for magnetic disks, ceramic substrates, and substrates for solar cells. Examples of the FPDs include liquid crystal display devices and organic electroluminescence (EL) display devices. Here, the back face of the substrate is a face where no electronic circuits are formed, which is opposite to a front face of the substrate as a face (device face) where electronic circuits are formed.

### BACKGROUND ART

A polishing device for polishing the back face of the substrate includes a holding rotator and a polishing head. The holding rotator rotates the substrate while holding the substrate in a horizontal posture. The polishing device supplies a polishing solution, and further causes the polishing head to contact against the back face of the rotating substrate for polishing the substrate (see, for example, Patent Literature 1).

Another type of polishing devices is a grinding device that performs dry-type chemo-mechanical grinding (CMG) to a substrate (see, for example, Patent Literature 2). The grinding device includes a holding rotator and a synthetic grindstone. The synthetic grindstone is formed by fixing a polishing agent (abrasive grain) with a resin binder. The grinding device grinds a substrate by contacting the synthetic grindstone against the substrate. Also, there is a substrate treating apparatus provided with a polisher for removing contaminants or contact marks on a back face of a substrate (see, for example, Patent Literature 3).

Patent Literature 4 discloses a grinding device provided with a grinding head. The grinding head includes a head body and an annular ring-shape grindstone. The annular ring-shape grindstone is located on a lower face of the head body. The lower face of the head body has a recess formed therein so as to correspond to a hollow portion at the center of the annular ring-shape grindstone. A suction hole communicating with a suction flow path is provided in an inner face of the recess.

### PRIOR ART DOCUMENT

### Patent Literature

### [Patent Literature 1]

Japanese Patent Publication No. 6162417

### [Patent Literature 2]

Japanese Patent Publication No. 6779540

### [Patent Literature 3]

Japanese Patent Publication No. 6740065

### [Patent Literature 4]

Japanese Unexamined Patent Publication No. 2021-053738

### SUMMARY OF INVENTION

### Technical Problem

The currently-used device having such a configuration has the following drawback. That is, the drawback is defocus (so-called out of focus) by an extreme ultraviolet (EUV) exposure device due to a substrate flatness of a back face of the substrate (e.g., wafer) in recent years. One cause of poor flatness is considered a scratch. As a result, in order to scrape off the scratch, it has been studied to adopt the synthetic grindstone as a polisher in Patent Literature 2. Here, it takes a long time to perform polishing treatment, and there is a desire to shorten time for the polishing treatment.

The present invention has been made regarding the state of the art noted above, and its object is to provide a substrate treating apparatus that can shorten time for polishing treatment.

### Solution to Problem

The present invention is constituted as stated below to achieve the above object. One aspect of the present invention provides a substrate treating apparatus. The substrate treating apparatus includes an indexer block which is provided with a carrier platform configured to place thereon a carrier that accommodates a substrate and in which the substrate is loaded and unloaded to and from the carrier placed on the carrier platform, a treating block in which predetermined treatment is performed on the substrate, and an interface block in which the substrate is loaded and unload to and from an external exposure device, the indexer block, the treating block, and the interface block being arranged horizontally and linearly in this order, the treating block including a coating block and a polishing block that are arranged horizontally and linearly, the coating block including a coating unit configured to coat a front face of the substrate with a resist, the polishing block including a polishing unit configured to polish a back face of the substrate, the polishing unit including a holding rotator configured to rotate the substrate while holding the substrate in a horizontal posture, a heating member configured to heat the substrate, and a polisher having a resin body where abrasive grains are distributed and configured to perform polishing to the back face of the substrate in a chemo-mechanical grinding manner by contacting against the back face of the substrate that is rotated while being heated.

The substrate treating apparatus according to the aspect of the present invention includes the polishing unit (the holding rotator, the polisher, and the heating member) and the coating unit. The polisher has a resin body in which abrasive grains are distributed. The polisher polishes the back face of the substrate in the chemo-mechanical grinding manner by contacting against the back face of the rotating substrate. The substrate is heated when polishing is performed. When the substrate is heated, a polishing rate can increase. This can shorten time for polishing treatment. Moreover, with the polishing unit and the coating unit, the resist is applied to the front face of the substrate, and the polishing is performed to the back face of the substrate. This achieves sufficient flatness of the substrate to which the resist is applied, whereby the defocus draw back of the exposure device can be overcome.

Moreover, it is preferred that the substrate treating apparatus described above further includes a controller, and that the controller adjusts a polishing rate by controlling a heating temperature of the substrate with the heating member when polishing is performed. Raising and lowering the heating temperature of the substrates allow increase and decrease of the polishing rate.

Moreover, it is preferred in the substrate treating apparatus described above that the controller adjusts the polishing rate by also controlling at least one selected from a contact pressure of the polisher against the substrate, a moving speed of the polisher, a rotation speed of the polisher, and a rotation speed of the substrate. For example, raising the heating temperature of the substrate while keeping the polishing rate allows decreased contact pressure of the polisher against the substrate. This can suppress load of the substrate caused by the contact pressure. That is, excess pushing against a substrate W can be prevented.

Moreover, it is preferred in the substrate treating apparatus described above that the holding rotator includes a spin base that is rotatable around a rotary axis extending in an up-down direction, and three or more holding pins that are provided on a top face of the spin base so as to surround the rotary axis in a ring shape, and configured to hold the substrate by sandwiching a side face of the substrate so that the substrate is held apart from the top face of the spin base, and that the heating member is exemplarily a first heater provided on the top face of the spin base. The substrate can be heated with the first heater provided on the top face of the spin base.

Moreover, it is preferred in the substrate treating apparatus described above that the holding rotator includes a spin base that is rotatable around a rotary axis extending in an up-down direction, and three or more holding pins that are provided on a top face of the spin base so as to surround the rotary axis in a ring shape, and configured to hold the substrate by sandwiching a side face of the substrate so that the substrate is held apart from the top face of the spin base, and that the heating member is exemplarily a gas ejection port that is opened in the top face of the spin base and provided in a center portion of the spin base, and configured to eject heated gas in such a manner that the gas flows in a gap between the substrate and the spin base from a portion adjacent to the center of the substrate to an outer edge of the substrate.

Heated gas from the gas ejection port can heat the substrate. Moreover, a device face (front face) of the substrate faces the spin base. When gas is ejected from the gas ejection port, gas jets outward from the gap between the outer edge of the substrate and the spin base. Accordingly, the polishing scraps or a liquid, for example, can be prevented from adhering to the device face of the substrate. That is, the device face of the substrate can be protected.

Moreover, it is preferred in the substrate treating apparatus described above that the heating member is exemplarily a second heater for heating the polisher. When the polisher is heated, the substrate can be heated via the polisher. Moreover, an interface between the polisher and the back face of the substrate can be heated effectively.

Moreover, it is preferred in the substrate treating apparatus described above that the heating member is exemplarily a heated water supply nozzle for supplying heated water to the back face of the substrate. Heated water can heat the substrate W. Moreover, heated water can clean off the polishing scraps from the back face of the substrate.

Moreover, it is preferred in the substrate treating apparatus described above that the treating block further includes a developing block in which developing treatment is performed on the substrate subjected to exposure treatment by the exposure device, and that the coating block, the polishing block, and the developing block are arranged horizontally and linearly.

Another aspect of the present invention provides a substrate treating apparatus. The substrate treating apparatus includes an indexer block which is provided with a carrier platform configured to place thereon a carrier that accommodates a substrate and in which the substrate is loaded and unloaded to and from the carrier placed on the carrier platform, a treating block in which predetermined treatment is performed on the substrate, and an interface block in which the substrate is loaded and unloaded to and from an external exposure device, the indexer block, the treating block, and the interface block being arranged horizontally and linearly in this order, the treating block including a coating unit configured to coat a front face of the substrate with a resist, the interface block including a polishing unit configured to polish a back face of the substrate coated with the resist by the coating unit, the polishing unit including a holding rotator configured to rotate the substrate while holding the substrate in a horizontal posture, a heating member configured to heat the substrate, and a polisher having a resin body where abrasive grains are distributed and configured to polish the back face of the substrate in a chemo-mechanical grinding manner by contacting against the back face of the substrate that is rotated while being heated.

Moreover, it is preferred in the substrate treating apparatus described above that the treating block includes a coating block and a developing block, that the coating block includes the coating unit and the developing block includes a developing unit configured to perform developing treatment on the substrate subjected to exposure treatment by the exposure device, and that the developing block is arranged between the coating block and the interface block.

Another aspect of the present invention provides a substrate treating apparatus. The substrate treating apparatus includes an indexer block which is provided with a carrier platform configured to place thereon a carrier that accommodates a substrate and in which the substrate is loaded and unloaded to and from the carrier placed on the carrier platform, a treating block in which predetermined treatment is performed on the substrate, and an interface block in which the substrate is loaded and unloaded to and from an external exposure device, the indexer block, the treating block, and the interface block being arranged horizontally and linearly in this order, that the treating block includes a coating layer and a polishing layer laminated in an up-down direction, the coating layer including a coating unit configured to coat a front face of the substrate with a resist, the polishing layer including a polishing unit configured to polish a back face of the substrate, and that the polishing unit including a holding rotator configured to rotate the substrate while holding the substrate in a horizontal posture, a heating member configured to heat the substrate, and a polisher having a resin body where abrasive grains are distributed and configured to polish the back face of the substrate in a chemo-mechanical grinding manner by contacting against the back face of the substrate that is rotated while being heated.

Moreover, it is preferred in the substrate treating apparatus described above that the treating block further includes a developing layer where developing treatment is performed on the substrate subjected to exposure treatment by the exposure device, and that the developing layer, the coating layer, and the polishing layer are stacked in the up-down direction.

Moreover, it is preferred that the substrate treating apparatus described above further includes an intermediate block arranged between the indexer block and the treating block, that the intermediate block includes a buffer group and a substrate transporting robot, the buffer group includes a plurality of substrate buffers arranged in the up-down direction and on each of which the substrate is placed, the substrate transporting robot transports the substrate among the plurality of substrate buffers, and the indexer block transports the substrate to and from the treating block via the buffer group. This can achieve efficient transportation of the substrate W on a side adjacent to the indexer block.

Another aspect of the present invention provides a substrate treating apparatus. The substrate treating apparatus includes a first treating block provided with a polishing unit configured to polish a back face of a substrate, an indexer block which is provided with a carrier platform configured to place thereon a carrier that accommodates a substrate and in which the substrate is loaded and unloaded to and from the carrier placed on the carrier platform, a second treating block provided with a coating unit configured to coat a front face of the substrate with a resist, and an interface block which is coupled to the first treating block or the second treating block horizontally and in which the substrate is loaded and unloaded to and from an external exposure device, the first treating block, the indexer block, and the second treating block being arranged horizontally and linearly in this order, the polishing unit including a holding rotator configured to rotate the substrate while holding the substrate in a horizontal posture, a heating member configured to heat the substrate, and a polisher having a resin body where abrasive grains are distributed and configured to polish the back face of the substrate in a chemo-mechanical grinding manner by contacting against the back face of the substrate that is rotated while being heated.

It is preferred in the substrate treating apparatus described above that the second treating block further includes a developing unit where developing treatment is performed on the substrate subjected to exposure treatment by the exposure device, and that the interface block is coupled to the second treating block horizontally.

### Advantageous Effects of Invention

The substrate treating apparatus according to the present invention can shorten time for polishing treatment.

### BRIEF DESCRIPTION OF DRAWINGS

FIG. 1 is a transverse cross-sectional view of a substrate treating apparatus according to a first embodiment.

FIG. 2 is a longitudinal cross-sectional view of the substrate treating apparatus according to the first embodiment.

FIG. 3 is a right side view of the substrate treating apparatus according to the first embodiment.

FIG. 4 is a side view of a polishing unit.

FIG. 5(a) is a plan view of a holding rotator, and FIG. 5(b) is a longitudinal sectional view of the construction of the holding rotator partially enlarged.

FIG. 6 illustrates a polishing mechanism of the polishing unit.

FIG. 7 illustrates an inspecting unit.

FIGS. 8(a) to 8(d) each illustrate an inversion unit.

FIG. 9 is a flow chart illustrating operation of the polishing unit according to the first embodiment.

FIG. 10(a) is a longitudinal sectional view schematically illustrating a substrate prior to an etching step, FIG. 10(b) is a longitudinal sectional view schematically illustrating the substrate after the etching step (prior to back polishing step), and FIG. 10(c) is a longitudinal sectional view schematically illustrating the substrate after the back polishing step.

FIG. 11 is a flow chart illustrating details of a wet-etching step.

FIG. 12 illustrates a relationship between a heating temperature and a polishing rate of the substrate.

FIG. 13 is a flow chart showing procedures of a substrate cleaning step.

FIG. 14 is a transverse cross-sectional view of a substrate treating apparatus according to a second embodiment.

FIG. 15 is a right side view of the substrate treating apparatus according to the second embodiment.

FIG. 16 is a longitudinal cross-sectional view of a substrate treating apparatus according to a third embodiment.

FIG. 17 is a right side view of the substrate treating apparatus according to the third embodiment.

FIG. 18 is a transverse cross-sectional view of the substrate treating apparatus (polishing layer) according to the third embodiment.

FIG. 19(a) is a transverse cross-sectional view of a coating layer, and FIG. 19(b) is a transverse cross-sectional view of a developing layer.

FIG. 20 is a longitudinal cross-sectional view of a substrate treating apparatus according to one modification of the third embodiment.

FIG. 21 is a longitudinal cross-sectional view of a substrate treating apparatus according to a fourth embodiment.

FIG. 22 is a right side view of the substrate treating apparatus according to the fourth embodiment.

FIG. 23 is a transverse cross-sectional view of an upper layer of the substrate treating apparatus according to the fourth embodiment.

FIG. 24 is a transverse cross-sectional view of a lower layer of the substrate treating apparatus according to the fourth embodiment.

FIG. 25 is a right side view of a substrate treating apparatus according to one modification of the fourth embodiment.

FIG. 26 illustrates a preferred construction of a polishing mechanism of a polishing unit according to a fifth embodiment.

FIG. 27 is a longitudinal cross-sectional view of a polishing head according to the fifth embodiment.

FIG. 28 is a bottom view of the polishing head according to the fifth embodiment.

FIG. 29 is a longitudinal cross-sectional view of a polishing head according to a sixth embodiment.

FIG. 30 is a bottom view of the polishing head according to the sixth embodiment.

FIG. 31 is a longitudinal cross-sectional view of a polishing head according to a seventh embodiment.

FIG. 32 is a bottom view of the polishing head according to the seventh embodiment.

FIG. 33 is a flow chart illustrating operation of a substrate treating apparatus according to an eighth embodiment.

FIG. 34 illustrates a relationship between a heating temperature of a substrate and a contact pressure (pushing pressure) of a polisher according to a ninth embodiment.

FIG. 35 is a side view illustrating a polishing unit according to a tenth embodiment.

FIG. 36 is a side view illustrating a liquid treating unit according to the tenth embodiment.

FIGS. 37(a) and (b) each illustrate a heater for heating a polisher according to another modification.

FIG. 38 illustrates a relationship between a combination of heating members and a heating temperature of a substrate according to another modification.

FIG. 39 is a longitudinal cross-sectional view of a substrate treating apparatus according to another modification.

### FIRST EMBODIMENT

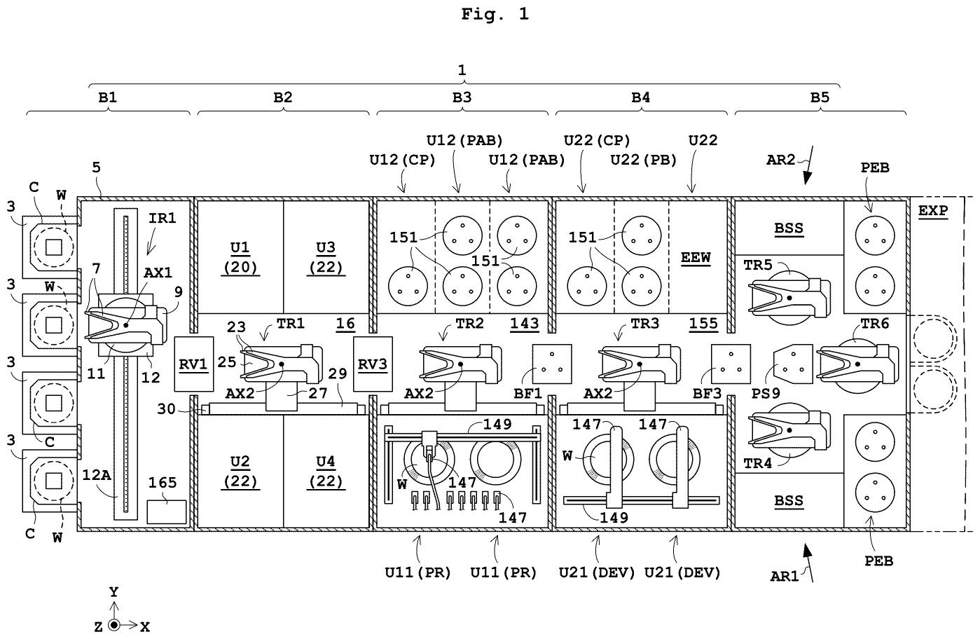

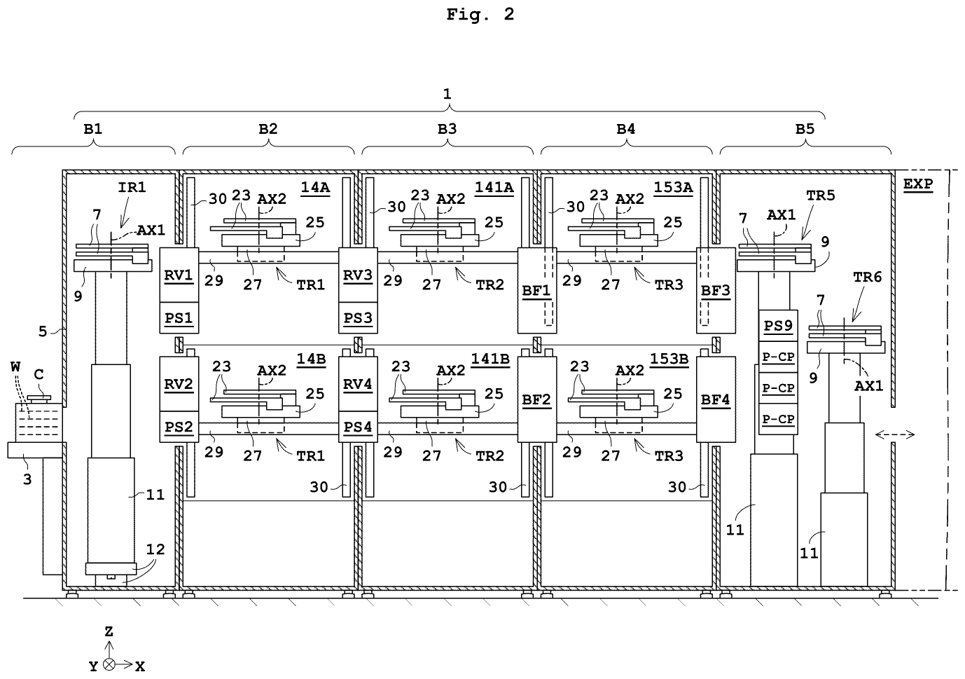

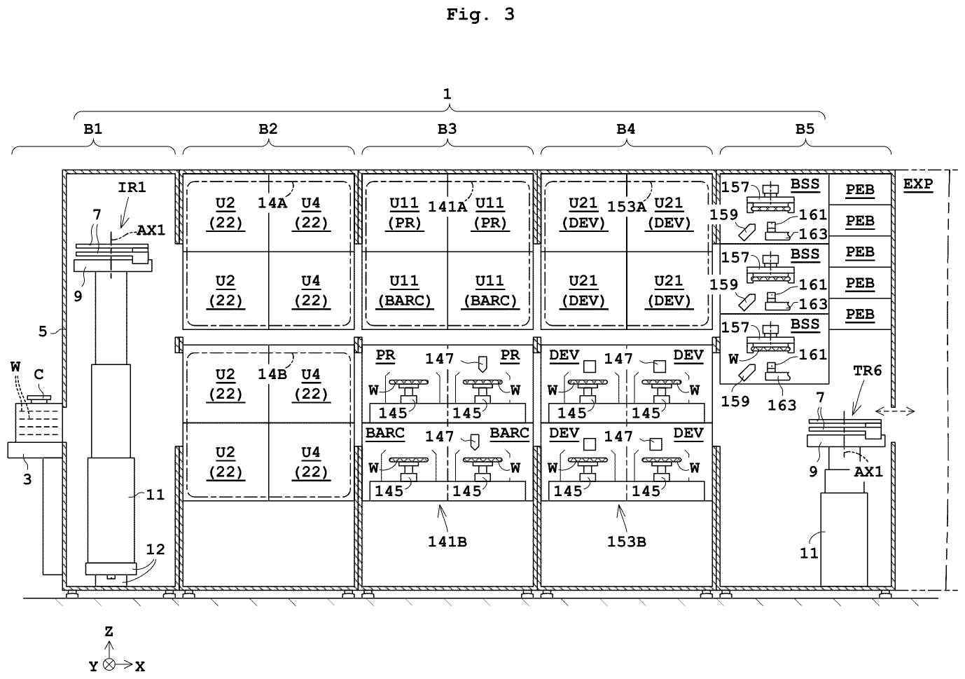

A first embodiment of the present invention will now be described with reference to the drawings. FIG. 1 is a transverse cross-sectional view of a substrate treating apparatus according to the first embodiment. FIG. 2 is a longitudinal cross-sectional view of the substrate treating apparatus according to the first embodiment. FIG. 3 is a right side view of the substrate treating apparatus according to the first embodiment.

### (1) Construction of Substrate Treating Apparatus 1

Reference is made to FIGS. 1 to 3. The substrate treating apparatus 1 includes an indexer block B1, a polishing block B2, a coating block B3, a developing block B4, and an interface block B5. Hereinafter, the interface block B5 is referred to as an “IF block B5”, where appropriate. The indexer block B1, the polishing block B2, the coating block B3, the developing block B4, and the IF block B5 are arranged horizontally and linearly in this order. Here, the block is called an area.

The polishing block B2, the coating block B3, and the developing block B4 each have a two-layered construction. That is, the polishing block B2 includes two polishing layers 14A and 14B. The coating block B3 includes two coating layers 141A and 141B. The developing block B4 includes two developing layers 153A and 153B.

The substrate treating apparatus 1 includes four inversion units RV1 to RV4, four substrate platforms PS1 to PS4, and four substrate buffers BF1 to BF4, as shown in FIG. 2. The four inversion units RV1 to RV4 each reverse front and back faces of a substrate W. Moreover, the substrate platforms PS1 to PS4 each place a substrate W thereon.

The inversion unit RV1 and the substrate platform PS1 are arranged between the indexer block B1 and the upper polishing layer 14A. The inversion unit RV2 and the substrate platform PS2 are arranged between the indexer block B1 and the lower polishing layer 14B. The inversion unit RV3 and the substrate platform PS3 are arranged between the upper polishing layer 14A and the upper coating layer 141A. The inversion unit RV4 and the substrate platform PS4 are arranged between the lower polishing layer 14B and the lower coating layer 141B. The details of the four inversion units RV1 to RV4 are to be mentioned later.

The substrate buffers BF1 to BF4 each include one more substrate platforms capable of placing one or more substrates W thereon. The substrate buffer BF1 is located between the upper coating layer 141A and the upper developing layer 153A. The substrate buffer BF2 is located between the lower coating layer 141B and the lower developing layer 153B. The substrate buffer BF3 is located between the upper developing layer 153A and the IF block B5. The substrate buffer BF4 is located between the lower developing layer 153B and the IF block B5. Note that the inversion unit RV1, the substrate platform PS1, and the substrate buffer BF1 and the like are arranged more forward than the substrate transporting robot TR1 and the like in FIG. 2 for convenience of illustration.

### (1-1) Construction of Indexer Block B1

The indexer block B1 includes, for example, four (plural) carrier platforms 3 and an indexer robot IR1. The four carrier platforms 3 are arranged on an outer face of a housing 5. The four carrier platforms 3 are each used for placing a carrier C thereon. The carrier C accommodates a plurality of substrates W. Each of the substrates W in the carrier C is in a horizontal posture while a device face thereof is directed upward (faces upward). For example, a FOUP (Front Open Unified Pod) or SMIF (Standard Mechanical Inter Face) pod, or an open cassette is used as the carrier C. The substrate W is a silicon substrate, and formed in a disk shape, for example.

The indexer robot IR1 takes a substrate W from a carrier C placed on the carrier platform 3, and also accommodates a substrate W into a carrier C. In other words, the indexer robot IR1 loads and unloads substrates W to and from the carriers C placed on the carrier platform 3. The indexer robot IR1 is located inside of the housing 5. Moreover, the indexer robot IR1 transports substrates W among the carriers C each placed on the carrier platform 3, the two inversion units RV1 and RV2, and the two substrate platforms PS1 and PS2.

The indexer robot IR1 includes two hands 7, a forward/rearward driving unit 9, a lifting/lowering rotation driving unit 11, and a horizontal drive unit 12. The two hands 7 each hold a substrate W. Moreover, each of the two hands 7 is attached to the forward/rearward driving unit 9 so as to be movable forward and rearward. The forward/rearward driving unit 9 is capable of moving the two hands 7 forward and rearward simultaneously. Moreover, the forward/rearward driving unit 9 is capable of moving the two hands 7 forward and rearward individually. The lifting/lowering rotation driving unit 11 lifts, lowers, and rotates the forward/rearward driving unit 9 to thereby lift, lower, and rotate the two hands 7. In other words, the lifting/lowering rotation driving unit 11 allows the forward/rearward driving unit 9 to move in an up-down direction (Z-direction) and to rotate the forward/rearward driving unit 9 about a vertical axis AX1.

The horizontal drive unit 12 includes a guide rail 12A extending in the Y-direction. The horizontal drive unit 12 moves the lifting/lowering rotation driving unit 11 in a Y-direction where the four carrier platforms 3 are lined. Thereby, the horizontal drive unit 12 is capable of moving the two hands 7 in the Y-direction. The forward/rearward driving unit 9, the lifting/lowering rotation driving unit 11, and the horizontal drive unit 12 each include an electric motor.

The indexer robot IR1 may include an articulated arm of a SCARA type and a lifting/lowering driving unit instead of the forward/rearward driving unit 9, the lifting/lowering rotation driving unit 11, and the horizontal drive unit 12. In this case, one or more hands 7 are provided on a distal end of the articulated arm and a proximal end of the articulated arm is attached to the lifting/lowering driving unit. The lifting/lowering driving unit moves the articulated arm in the up-down direction (Z-direction). The articulated arm and the lifting/lowering driving unit each include an electric motor. The lifting/lowering driving unit may be configured to be movable in the Y-direction. Alternatively, the lifting/lowering driving unit may be fixed to the floor or an inner wall of the housing without moving in the Y-direction.

### (1-2) Construction of Polishing Block B2

The polishing block B2 includes two polishing layers 14A and 14B laminated in the up-down direction. The polishing layer 14A has a construction substantially same as that of the polishing layer 14B. Accordingly, the upper polishing layer 14A will be described as a representative example. The upper polishing layer 14A includes a transportation space 16, a substrate transporting robot TR1, and eight (plural) treating units U1 to U4.

The four treating units U1 to U4 are each formed in two layers (see FIG. 3). The treating unit U1 is an inspecting unit 20. The treating units U2, U3, and U4 each are a polishing unit 22. The number and types of the treating units U1 to U4 are appropriately variable.

The substrate transporting robot TR1 is located in the transportation space 16. The transportation space 16 is configured to extend in the X-direction in plan view. The treating units U1 and U3 are arranged in a row along the transportation space 16 in an X-direction. Moreover, the treating units U2 and U4 are arranged in a row along the transportation space 16 in the X-direction. The transportation space 16 is arranged between the treating units U1, U3 and the treating units U2, U4.

The substrate transporting robot TR1 transports substrates W among the two inversion units RV1 and RV3, the two substrate platforms PS1 and PS3, and the eight treating units U1 to U4. The substrate transporting robot TR1 includes two hands 23, a forward/rearward driving unit 25, a rotation driving unit 27, a horizontal drive unit 29, and a lifting/lowering driving unit 30.

The two hands 23 each hold a substrate W. The two hands 23 are each attached to the forward/rearward driving unit 25 so as to be movable forward and rearward. The forward/rearward driving unit 25 moves the two hands 23 forward and rearward. The rotation driving unit 27 rotates the forward/rearward driving unit 25 about a vertical axis AX2. This changes orientation of the two hands 23. The horizontal drive unit 29 moves the rotation driving unit 27 in the X-direction. Moreover, the lifting/lowering driving unit 30 moves the horizontal drive unit 29 in the Z-direction. The two hands 23 are moved by the horizontal drive unit 29 and the lifting/lowering driving unit 30 in the XZ-direction. The forward/rearward driving unit 25, the lifting/lowering rotation driving unit 27, the horizontal drive unit 29, and the lifting/lowering driving unit 30 each include an electric motor.

### (1-1-2) Polishing Unit 22

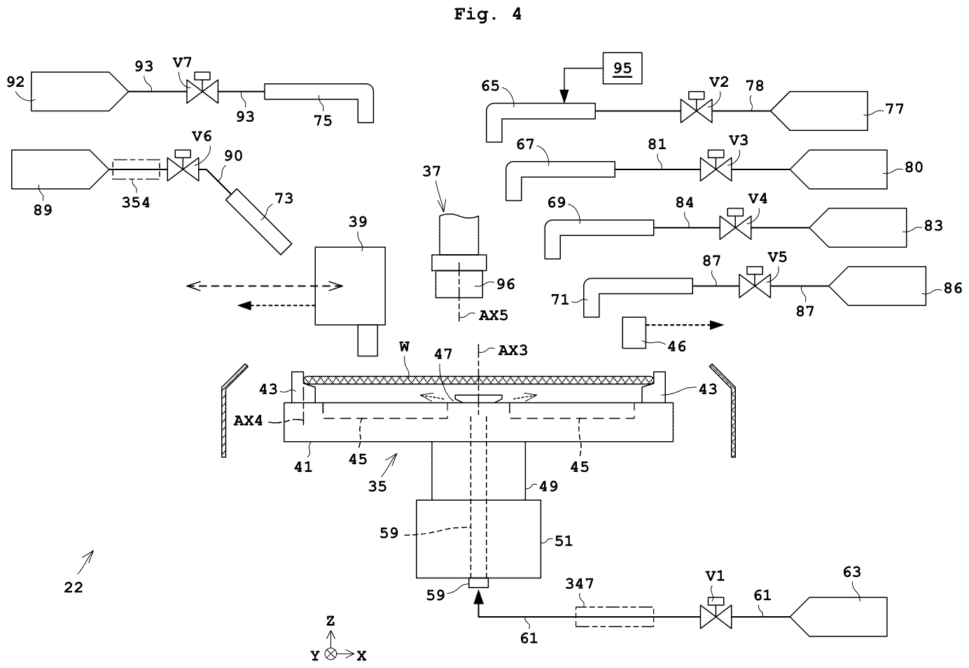

FIG. 4 shows the polishing unit 22. The polishing unit 22 polishes the back face of the substrate W. The polishing unit 22 includes a holding rotator 35, a polishing mechanism 37, and a substrate thickness measuring device 39. The holding rotator 35 corresponds to the holding rotator in the present invention.

The holding rotator 35 holds one substrate W whose back face is directed upward in a horizontal posture, and rotates the held substrate W. Here, the back face of the substrate W is a face where no electronic circuits are formed, which is opposite to a front face of the substrate W as a face (device face) where electronic circuits are formed. The device face of the substrate W held by the holding rotator 35 is directed downward. The holding rotator 35 includes a spin base 41, six holding pins 43, a hot plate 45, and a gas ejection port 47. The spin base 41 is formed in a disk shape, and is arranged in a horizontal posture. A rotary axis AX3, extending in the up-down direction, passes the center of the spin base 41. The spin base 41 is rotatable around the rotary axis AX3.

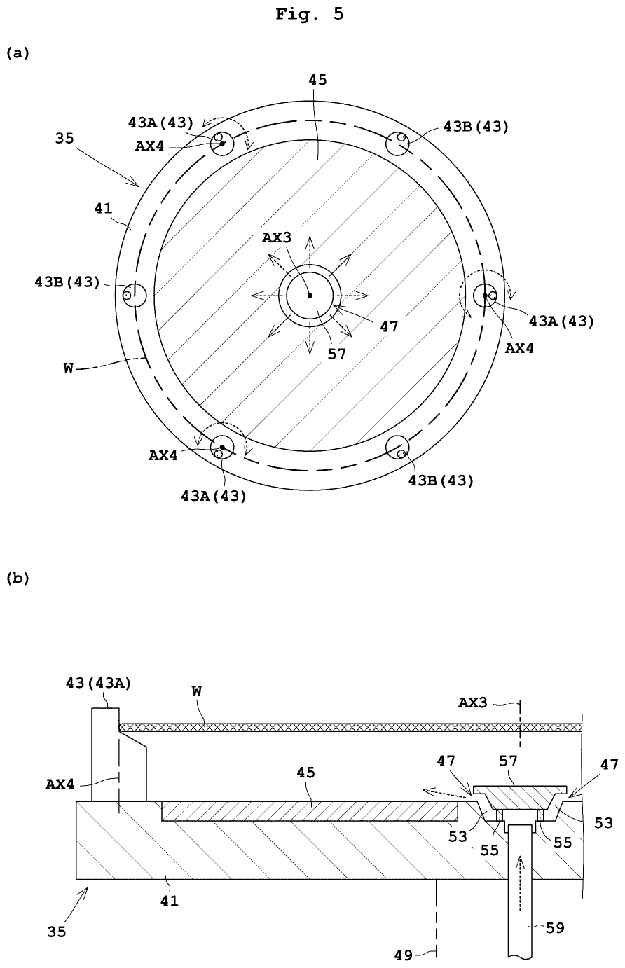

FIG. 5(a) is a plan view of the spin base 41 and the six holding pins 43 of the holding rotator 35. The six holding pins 43 are provided on a top face of the spin base 41. The six holding pins 43 are provided in a ring shape so as to surround the rotary axis AX3. Moreover, the six holding pins 43 are provided at equal intervals near an outer edge of the spin base 41. The six holding pins 43 cause the substrate W to be placed apart from the spin base 41 and the hot plate 45 mentioned later. Moreover, the six holding pins 43 are configured so as to sandwich a side face of the substrate W. That is, the six holding pins 43 can hold the substrate W while the substrate W is apart from the top face of the spin base 41.

The six holding pins 43 are divided into three holding pins 43A that rotate, and three holding pins 43B that do not rotate. The three holding pins 43A are rotatable around a rotary axis AX4 extending in the up-down direction. The three holding pins 43A each rotate around the rotary axis AX4, thereby holding the substrate W and releasing the held substrate W. The holding pins 43A each rotate around the rotary axis AX4 by magnetic suction force or repulsion by a magnet, for example. The number of holding pins 43 is not limited to six, and the number only needs to be three or more. The substrate W may be held by three or more holding pins 43 including a holding pin 43A that rotates and a holding pin 43B that does not rotate.

The hot plate 45 is provided on the top face of the spin base 41. The hot plate 45 includes therein an electric heater having a nichrome wire, for example. The hot plate 45 is formed in a toroidal and disk shape. The hot plate 45 heats the substrate W with radiant heat. Moreover, the hot plate 45 heats gas ejected from the gas ejection port 47, mentioned later, thereby heating the substrate W through the gas. A temperature sensor 46 of a non-contact type determines a temperature of the substrate W. The temperature sensor 46 includes a detecting element configured to detect infrared rays emitted from the substrate W. Here, the hot plate 45 corresponds to the heating member in the present invention. Moreover, in the embodiment 1, the polishing unit 22 does not include heaters 347, 354 (see FIG. 4) mentioned later.

A shaft 49 is provided on a lower face of the spin base 41. A rotating mechanism 51 includes an electric motor. The rotating mechanism 51 rotates the shaft 49 around the rotary axis AX3. That is, the rotating mechanism 51 rotates the substrate W, held by the six holding pins 43 (specifically, three holding pins 43A) provided on the spin base 41, around the rotary axis AX3.

Reference is made to FIG. 4 and FIG. 5(b). The gas ejection port 47 is opened in the top face of the spin base 41 and is provided at a center portion of the spin base 41. A flow path 53 whose upper part is opened is provided at the center of the spin base 41. Moreover, an ejection member 57 is provided in the flow path 53 via a plurality of spacers 55. The gas ejection port 47 is configured by a ring opening that is formed by a gap between the ejection member 57 and the flow path 53.

A gas supplying pipe 59 is provided along the rotary axis AX3 so as to pass through the shaft 49 and the rotating mechanism 51. A gas pipe 61 feeds gas (inert gas such as nitrogen gas) from a gas supplying source 63 to the gas supplying pipe 59. An on-off valve V1 is provided on the gas pipe 61. The on-off valve V1 performs and stops supply of the gas. When the on-off valve V1 is opened, the gas ejection port 47 ejects gas. When the on-off valve V1 is closed, the gas ejection port 47 does not eject gas. The gas ejection port 47 ejects gas in such a manner that the gas flows in a gap between the substrate W and the spin base 41 from a portion adjacent to the center of the substrate W toward the outer edge of the substrate W.

The following describes a construction for supplying a chemical liquid, a rinse liquid, and gas. The polishing unit 22 includes a first chemical liquid nozzle 65, a second chemical liquid nozzle 67, a first cleaning liquid nozzle 69, a second cleaning liquid nozzle 71, a rinse liquid nozzle 73, and a gas nozzle 75.

The first chemical liquid nozzle 65 is connected to a chemical liquid pipe 78 that feed a first chemical liquid from a first chemical liquid supplying source 77. The first chemical liquid is, for example, hydrofluoric acid (HF). An on-off valve V2 is provided on the chemical liquid pipe 78. The on-off valve V2 performs and stops supply of the first chemical liquid. When the on-off valve V2 is opened, the first chemical liquid is supplied from the first chemical liquid nozzle 65. Moreover, when the on-off valve V2 is closed, supply of the first chemical liquid from the first chemical liquid nozzle 65 stops.

The second chemical liquid nozzle 67 is connected to a chemical liquid pipe 81 that feed a second chemical liquid from a second chemical liquid supplying source 80. The second chemical liquid is, for example, a mixed liquid of hydrofluoric acid (HF) and nitric acid (HNO₃), tetramethylammonium hydroxide (TMAH), or hot diluted ammonia water (hot-dNH₄OH). An on-off valve V3 is provided on the chemical liquid pipe 81. The on-off valve V3 performs and stops supply of the second chemical liquid. Here, the first chemical liquid and the second chemical liquid correspond to the etching solution in the present invention.

The first cleaning liquid nozzle 69 is connected to a cleaning liquid pipe 84 that feed a first cleaning liquid from a first cleaning liquid supplying source 83. The first cleaning liquid is, for example, SC2 or SPM. Here, SC2 is a mixed liquid of hydrochloric acid (HCl), hydrogen peroxide (H₂O₂), and water. SPM is a mixed liquid of sulfuric acid (H₂SO₄) and hydrogen peroxide water (H₂O₂). An on-off valve V4 is provided on the cleaning liquid pipe 84. The on-off valve V4 performs and stops supply of the first cleaning liquid.

The second cleaning liquid nozzle 71 is connected to a cleaning liquid pipe 87 that feed a second cleaning liquid from a second cleaning liquid supplying source 86. The second cleaning liquid is, for example, SC1. SC1 is a mixed liquid of ammonia, hydrogen peroxide water (H₂O₂), and water. An on-off valve V5 is provided on the cleaning liquid pipe 87. The on-off valve V5 performs and stops supply of the second cleaning liquid.

The rinse liquid nozzle 73 is connected to a rinse liquid pipe 90 that feeds a rinse liquid from a rinse liquid supplying source 89. The rinse liquid is, for example, pure water like deionized water (DIW) or carbonated water. An on-off valve V6 is provided on the rinse liquid pipe 90. The on-off valve V6 performs and stops supply of the rinse liquid.

The gas nozzle 75 is connected to a gas pipe 93 that feeds gas from a gas supplying source 92. The gas is, for example, inert gas like nitrogen gas. An on-off valve V7 is provided on the gas pipe 93. The on-off valve V7 performs and stops supply of the gas.

The first chemical liquid nozzle 65 is moved by a nozzle moving mechanism 95 in a horizontal direction. The nozzle moving mechanism 95 includes an electric motor. The nozzle moving mechanism 95 may rotate the first chemical liquid nozzle 65 around a vertical axis (not shown) set in advance. Moreover, the nozzle moving mechanism 95 may move the first chemical liquid nozzle 65 in the X-direction and the Y-direction. Moreover, the nozzle moving mechanism 95 may move the first chemical liquid nozzle 65 in the up-down direction (Z-direction). Similar to the first chemical liquid nozzle 65, the five nozzles 67, 69, 71, 73, and 75 each may be moved by the nozzle moving mechanism (not shown).

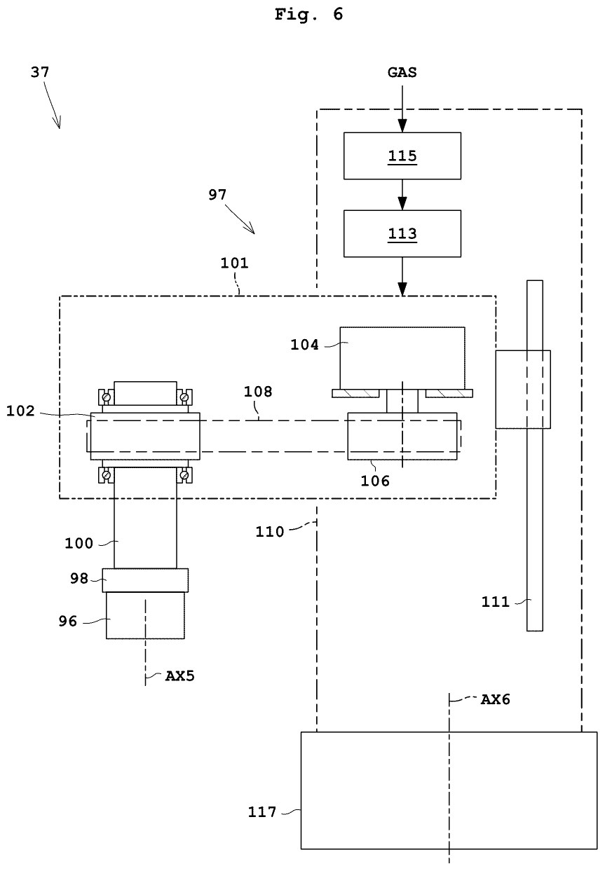

The following describes the construction of the polishing mechanism 37. The polishing mechanism 37 polishes the back face of the substrate W. FIG. 6 is a side view of the polishing mechanism 37. The polishing mechanism 37 includes a polisher 96 and a polisher moving mechanism (head drive mechanism) 97. The polisher moving mechanism 97 includes an attachment member 98, a shaft 100, and an arm 101.

The polisher (grinder) 96 polishes the back face of the substrate W in a dry chemo-mechanical grinding (CMG) manner. The polisher 96 is formed in a cylindrical shape. The polisher 96 has a resin body in which abrasive grains are distributed. In other words, the polisher 96 is formed by fixing the abrasive grains (polishing agent) with a resin binder. An oxide such as cerium oxide or silica is used as the abrasive grains. It is preferred that the abrasive grain has an average particle size of 10 μm or less. Thermosetting resin such as epoxy resin and phenol resin is used for the resin body and resin binder. Moreover, thermoplastics such as ethyl cellulose may be used for the resin body and resin binder. In this case, polishing is performed such that the thermoplastics is not softened.

Now description will be made of the chemo-mechanical grinding (CMG). In the CMG, grinding is considered to be performed by the following principle. That is, local high temperatures and high pressure in the vicinity of the abrasive grain occur due to contact of the abrasive grain like cerium oxide and an object, leading to generation of a solid phase reaction between the abrasive grain and the object to form silicates. As a result, a surface layer of the object is softened, and the softened surface layer is mechanically removed by the abrasive grains. Here, examples of the polishing include a chemical mechanical polishing (CMP) manner. In this manner, a slurry solution is supplied to a pad which is brought into contact with the object, and the abrasive grains contained in the slurry solution are kept on an uneven surface of the pad to perform chemical mechanical polishing. The present invention adopts the CMG manner.

The polisher 96 is attachable to and detachable from the attachment member 98 via a screw, for example. The attachment member 98 is fixed to a lower end of the shaft 100. A pulley 102 is fixed to the shaft 100. An upper end of the shaft 100 is accommodated in the arm 101. That is, the polisher 96 and the attachment member 98 are attached to the arm 101 via the shaft 100.

An electric motor 104 and a pulley 106 are arranged within the arm 101. The pulley 106 is connected to a rotation output shaft of the electric motor 104. A belt 108 passes over the two pulleys 102 and 106. The pulley 106 is rotated by the electric motor 104. Rotation of the pulley 106 is transmitted to the pulley 102 and the shaft 100 by the belt 108. Accordingly, the polisher 96 rotates around a vertical axis AX5.

Moreover, the polisher moving mechanism 97 includes a lifting mechanism 110. The lifting mechanism 110 includes a guide rail 111, an air cylinder 113, and an electropneumatic regulator 115. A proximal end of the arm 101 is connected to the guide rail 111 so as to be movable upward and downward. The guide rail 111 guides the arm 101 in the up-down direction. The air cylinder 113 moves the arm 101 upward and downward. The electropneumatic regulator 115 supplies gas, such as air with pressure set in accordance with an electrical signal from a main controller 165 mentioned later, to the air cylinder 113. Now; the lifting mechanism 110 may include a linear actuator, instead of the air cylinder 113, that is driven by an electric motor.

Moreover, the polisher moving mechanism 97 further includes an arm rotating mechanism 117. The arm rotating mechanism 117 includes an electric motor. The arm rotating mechanism 117 rotates the arm 101 and the lifting mechanism 110 around a vertical axis AX6. That is, the arm rotating mechanism 117 rotates the polisher 96 around the vertical axis AX6.

The polishing unit 22 includes the substrate thickness measuring device 39. The substrate thickness measuring device 39 measures a thickness of the substrate W held by the holding rotator 35. The substrate thickness measuring device 39 is configured to emit light in a wavelength range (e.g., 1100 nm to 1900 nm) that is transparent to the substrate W from a light source to a mirror and the substrate W through an optical fiber. Moreover, the substrate thickness measuring device 39 is configured to detect returned light caused by interference of reflected light by the mirror, reflected light reflected on the upper surface of the substrate W, and reflected light reflected on the lower surface of the substrate W with use of light receiving elements. Then, the substrate thickness measuring device 39 generates a spectral interference waveform representing a relationship between the wavelength of the return light and light intensity, and analyzes the spectral interference waveform to measure a thickness of the substrate W. The substrate thickness measuring device 39 is a known device. The substrate thickness measuring device 39 may be configured so as to be movable by a moving mechanism not shown between a standby position out of the substrate W and a measuring position above the substrate W.

### (1-2-2) Inspecting Unit 20

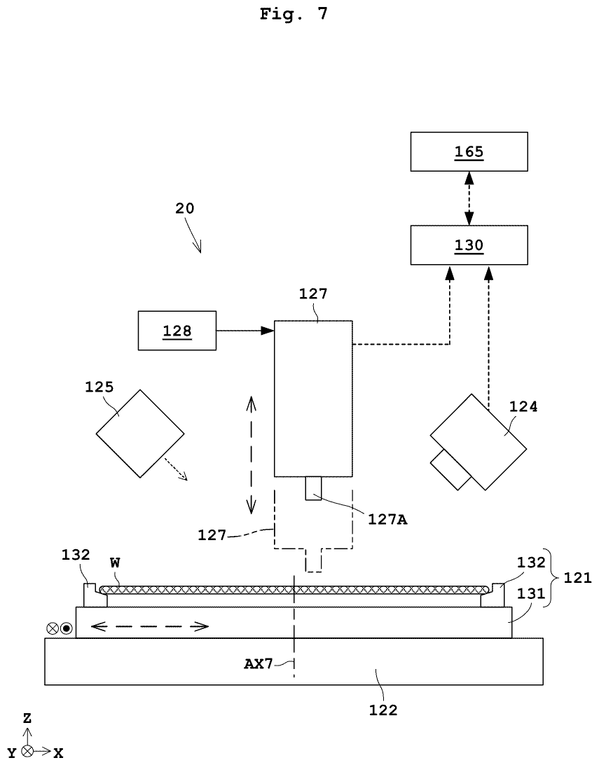

FIG. 7 is a side view of the inspecting unit 20. The inspecting unit 20 includes a stage 121, an XY-direction moving mechanism 122, a camera 124, a lighting portion 125, a laser scanning confocal microscope 127, a lifting mechanism 128, and an inspection controller 130.

The stage 121 supports the substrate W, whose back face is directed upward, in a horizontal posture. The stage 121 includes a disk base member 131 and six support pins 132, for example. The six support pins 132 are provided in a ring shape around a central axis AX7 of the base member 131. Moreover, the six support pins 132 are arranged at equal intervals in a circumferential direction. With such a construction, the six support pins 132 can support the outer edge of the substrate W while the substrate W is separated from the base member 131. Moreover, the XY-direction moving mechanism 122 moves the stage 121 in the XY-direction (horizontal direction). The XY-direction moving mechanism 122 includes, for example, two linear actuators each driven by an electric motor.

The camera 124 takes a picture of the back face of the substrate W. The camera 124 includes an image sensor such as a charge-coupled device (CCD) or a complementary metal-oxide semiconductor (CMOS). The lighting portion 125 emits light to a back face of a substrate W. This allows easy observation of a scratch generated on the back face of the substrate W, for example.

The laser scanning confocal microscope 127 is hereunder called a “laser microscope 127”. The laser microscope 127 includes a confocal optical system having a laser light source, an objective lens 127A, an imaging lens, an optical sensor, and a confocal pinhole. The laser microscope 127 captures a plane image by scanning the laser light source in the XY-direction (horizontal direction). Moreover, the laser microscope 127 captures plane images by moving the objective lens 127A in the Z-direction (height direction) relative to the object to be observed. As a result, the laser microscope 127 captures a three-dimensional image (a plurality of plane images) containing a three-dimensional shape. Here, the laser microscope 127 is called a three-dimensional shape measuring device.

The laser microscope 127 captures a three-dimensional image of any scratch generated on the back face of the substrate W. For example, a controller mentioned later determines a depth of the scratch from the three-dimensional shape of the scratch in the captured three-dimensional image. The lifting mechanism 128 moves the laser microscope 127 upward and downward in the up-down direction (Z-direction). The lifting mechanism 128 is formed by a linear actuator driven by an electric motor.

### (1-2-3) Inversion Units RV1 to RV4

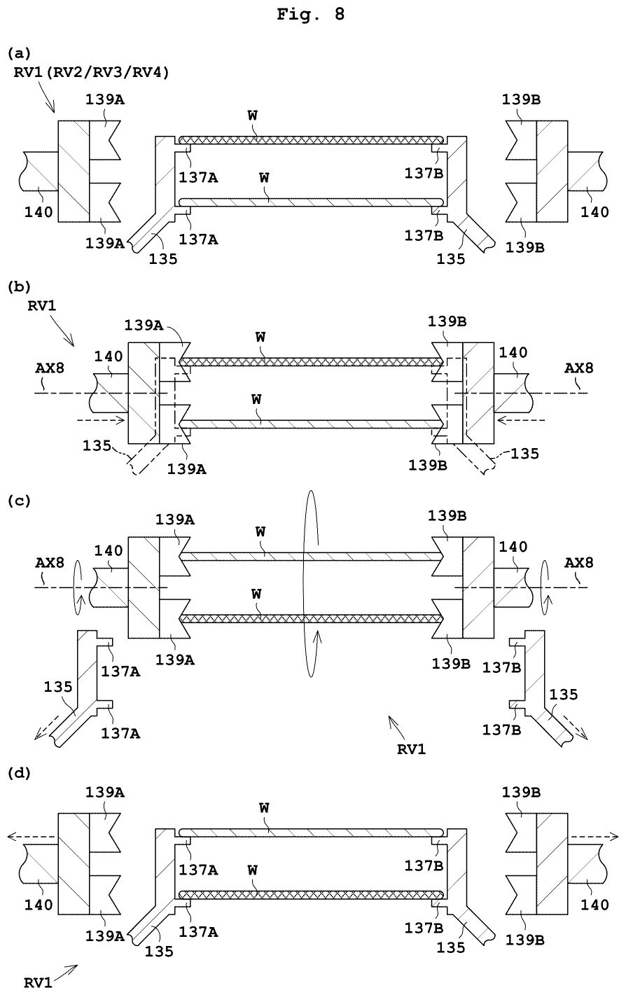

FIGS. 8(a) to 8(d) each illustrate the inversion units RV1 to RV4. The substrate treating apparatus 1 includes the four inversion units RV1 to RV4 (see FIG. 2). The inversion unit RV1 is configured in the same manner as each of the three inversion units RV2 to RV4. Accordingly, the inversion unit RV1 will be described as a representative example.

The inversion unit RV1 includes supporting members 135, mount members 137A, 137B, grasping members 139A, 139B, slide shafts 140, and a plurality of electric motors (not shown). Right and left supporting members 135 have the mount members 137A and 137B, respectively. Moreover, right and left slide shafts 140 have the grasping members 139A and 139B, respectively. The electric motors drive the supporting members 135 and the slide shafts 140. Here, the mount members 137A and 137B and the grasping members 139A and 139B are positioned so as not to interfere with each other.

Reference is made to FIG. 8(a). A substrate W, transported by the indexer robot IR1, for example, is placed on each of the mount members 137A and 137B. Reference is made to FIG. 8(b). The right and left slide shafts 140 approach each other along a horizontal axis AX8. Accordingly, the grasping members 139A and 139B sandwich two substrates W individually. Reference is made to FIG. 8(c). Then, the right and left mount members 137A and 137B move downward and away from each other. Then, the grasping members 139A and 139B rotate by 180 degrees around the horizontal axis AX8. This reverses each of the substrates W.

Reference is made to FIG. 8(d). Then, the right and left mount members 137A and 137B move upward while approaching each other. Then, the right and left slide shafts 140 move away from each other along the horizontal axis AX8. Accordingly, the grasping members 139A, 139B release the two substrates W, and the two substrates W are placed on the mount members 137A, 137B. In FIGS. 8(a) to 8(d), the inversion unit RV1 can reverse the two substrates W. Alternatively, the inversion unit RV1 may be configured to be capable of reversing three or more substrates W.

### (1-3) Construction of Coating Block B3

Reference is made to FIGS. 1 to 3. The coating block B3 includes two coating layers 141A and 141B laminated in the up-down direction. The upper coating layer 141A is configured in substantially the same manner as the lower coating layer 141B. Accordingly, the upper coating layer 141A will be described as a representative example. The upper coating layer 141A includes a transportation space 143, a substrate transporting robot TR2, exemplarily four (plural) liquid treating units U11, and a plurality of treating units U12.

The substrate transporting robot TR2 is provided in the transportation space 143. The substrate transporting robot TR2 is constructed in the same manner as the substrate transporting robot TR1 in the polishing layer 14A. In the upper coating layer 141A, the substrate transporting robot TR2 transports substrates W among the inversion unit RV3, the substrate platform PS3, the substrate buffer BF1, the four liquid treating units U11, and the treating units U12.

As shown in FIG. 1, the four liquid treating units U11 and the treating units U12 are arranged across the transportation space 143. As shown in FIG. 3, the four liquid treating units U11 are arranged in two stages in the up-down direction (Z-direction), each stage having two units U11 in the horizontal direction (X-direction). For example, when the coating layer 141A includes fifteen treating units U12, the fifteen treating units U12 are arranged in five stages in the up-down direction (Z-direction), each stage having three treating units U12 in the horizontal direction (X-direction).

As shown in FIGS. 1 and 3, the liquid treating units U11 includes a holding rotator 145, nozzles 147, and a nozzle moving mechanism 149. The holding rotator 145 is configured to rotate the substrate W around the vertical axis while holding the substrate W in a horizontal posture. The holding rotator 145 holds the substrate W by suction-holding a lower surface of the substrate W or sandwiching an end face of the substrate W in the horizontal direction. The holding rotator 145 includes an electric motor for rotating the substrate W. The nozzles 147 dispense a resist liquid or a chemical liquid for forming an antireflection film, for example. A pipe having an on-off valve provided thereon is connected to each of the nozzles 147. The nozzle moving mechanism 149 is configured to move the nozzles 147 to any positions. The nozzle moving mechanism 149 includes, for example, a linear actuator driven by an electric motor.

As the liquid treating unit U11, a coating unit PR configured to coat a front face of the substrate W with the resist, for example. In addition, as for the liquid treating unit U11, a coating unit BARC configured to form an antireflection film may be used, for example. In FIG. 3, two coating units BARC are arranged in a lower stage of the coating layer 141A. Moreover, two coating units PR are arranged in an upper stage of the coating layer 141A.

As for the treating unit U12, a cooling unit CP and a heat treating unit PAB are used, for example. The cooling units CP cool the substrates W. The heat treating units PAB perform a bake treatment on a substrate W after coating. The heat treating units PAB, a post-exposure bake treatment units PEB (mentioned later), and a post-bake unit PB (mentioned later) each have a cooling function. When the substrate W is heated, the treating units U12 and treating units U22 mentioned later each include a plate 151 on which the substrate W is placed and a heater (e.g., electric heater), for example. When the substrate W is cooled, the treating units U12 and treating units U22 mentioned later each include a plate 151 and a water-cooled circulating mechanism or a Peltier element, for example.

### (1-4) Construction of Developing Block B4

Reference is made to FIGS. 1 to 3. The developing block B4 includes two developing layers 153A and 153B laminated in the up-down direction. The upper developing layer 153A is configured in substantially the same manner as the lower developing layer 153B. Accordingly, the upper developing layer 153A will be described as a representative example. The upper developing layer 153A includes a transportation space 155, a substrate transporting robot TR3, exemplarily four (plural) liquid treating units U21, and a plurality of treating units U22. These elements 155, TR3, U21, and U22 are arranged in the same manner as the elements 143, TR2, U11, and U12, respectively, of the coating layer 141A.

The substrate transporting robot TR3 is constructed in the same manner as the substrate transporting robot TR1 in the polishing layer 14A. In the upper developing layer 153A, the substrate transporting robot TR3 transports substrates W among the two substrate buffers BF1, BF3, the four liquid treating units U21, and the treating units U22.

A developing unit DEV is used as the liquid treating unit U21. The developing unit DEV performs the developing treatment on the substrate W subjected to the exposure treatment by the exposure device EXP. The developing unit DEV includes a holding rotator 145, nozzles 147, and a nozzle moving mechanism 149, which is similar to the liquid treating unit U11. The nozzles 147 eject a developing solution to the substrate W.

Moreover, as for the treating unit U22, a cooling unit CP, a post-bake unit PB, and an edge exposing unit EEW are used, for example. The post-bake units PB each perform a bake treatment on the substrate W after the developing treatment. The edge exposing units EEW expose a peripheral edge of the substrate W.

### (1-5) Construction of Interface Block (IF Block) B5

The IF block B5 loads and unloads the substrate W into and from an external exposure device EXP. The IF block B5 includes three substrate transporting robots TR4, TR5, TR6, a plurality of back face cleaning units BSS, a plurality of post-exposure bake treatment units PEB, a substrate platform PS9, and three mounting-cum-cooling units P-CP.

The three substrate transporting robots TR4, TR5, TR6 are each constructed in substantially the same manner as the indexer robot IR1 except that no horizontal drive unit 12 is provided. The two substrate transporting robots TR4 and TR5 are arranged in the Y-direction. The developing block B4 and the substrate transporting robot TR6 are arranged across the two substrate transporting robots TR4, TR5.

The substrate transporting robot TR4 transports substrates W among the two substrate buffers BF3, BF4, the back face cleaning units BSS (side of arrow AR1), the post-exposure bake treatment units PEB (the side of arrow AR1), the substrate platform PS9, and the three mounting-cum-cooling units P-CP.

The substrate transporting robot TR5 transports substrates W among the two substrate buffers BF3, BF4, the back face cleaning units BSS (side of arrow AR2), the post-exposure bake treatment units PEB (the side of arrow AR2), the substrate platform PS9, and the three mounting-cum-cooling units P-CP. The substrate transporting robot TR6 transports substrates W among the external exposure device EXP, the substrate platform PS9, and the three mounting-cum-cooling units P-CP.

The back face cleaning unit BSS cleans a back face of the substrate W with a cleaning liquid supplied to the back face of the substrate W and a brush. The back face cleaning unit BSS includes a holding rotator 157, a nozzles 159, a brush 161, and a brush moving mechanism 163 (see FIG. 3). The holding rotator 157 holds the substrate W, whose front face is directed upward, from the above of the substrate W. The holding rotator 157 holds an outer edge of the substrate W in a horizontal posture, thereby holding the substrate W. The back face of the substrate W held by the holding rotator 157 is directed downward.

The nozzles 159 supply a cleaning liquid to the back face of the substrate W. The brush 161 adopts a sponge brush of polyvinyl alcohol (PVA), for example. The brush moving mechanism 163 moves the brush 161 in the horizontal direction and the up-down direction, which is similar to the polisher moving mechanism 97 in FIG. 6. The brush moving mechanism 163 cleans the back face of the substrate W by contacting the brush 161 against the back face of the rotating substrate W to which the cleaning liquid is supplied. Here, the holding rotator 157 and the brush moving mechanism 163 each include an electric motor.

The post-exposure bake treatment units PEB perform a heating treatment on the substrate W after exposure. The substrate platform PS9 and the three mounting-cum-cooling units P-CP are arranged in the up-down direction. Moreover, the substrate platform PS9 and the three mounting-cum-cooling units P-CP are surrounded by the three substrate transporting robots TR4 to TR6 in plan view. The substrate platform PS9 places the substrates W thereon. The mounting-cum-cooling units P-CP each have the substrate W placed thereon, and cool the substrate W like the cooling unit CP.

Here, the number and types of the treating units U11, U12, U21, and U22 are appropriately variable. Moreover, the number of the back face cleaning units BSS, the post-exposure bake treatment units PEB, the substrate platforms PS1 to PS4, PS9, and the mounting-cum-cooling units P-CP are appropriately variable.

Here in the lower polishing layer 14B, the substrate transporting robot TR1 in the polishing layer 14B transports substrates W among the two inversion units RV2 and RV4, the two substrate platforms PS2 and PS4, and the eight (four by two stages) treating units U1 to U4. In the lower coating layer 141B, the substrate transporting robot TR2 in the coating layer 141B transports substrates W among the inversion unit RV4, the substrate platform PS4, the substrate buffer BF2, the four liquid treating units U11, and the treating units U12. Moreover, in the lower developing layer 153B, the substrate transporting robot TR3 in the developing layer 153B transports substrates W among the two substrate buffers BF2, BF4, the four liquid treating units U21, and the treating units U22.

### (1-6) Construction about Control of Substrate Treating Apparatus 1

Reference is made again to FIG. 1. The substrate treating apparatus 1 includes a main controller 165 and a memory unit (not shown). The main controller 165 controls each component. The main controller 165 includes one or more processors like a central processing unit (CPU), for example. The memory unit includes, for example, at least one of a read-only memory (ROM), a random-access memory (RAM), and a hard disk. The memory unit stores computer programs and the like necessary for controlling each component of the substrate treating apparatus 1. The main controller 165 is communicably connected to the inspection controller 130 of the inspecting unit 20 in the polishing block B2.

Here, the polishing block B2 and the coating block B3, or the polishing block B2, the coating block B3 and the developing block B4 correspond to the treating blocks where predetermined treatment is performed on the substrate in the present invention.

### (2) Operation of Substrate Treating Apparatus 1

Next, description will be given of operation of the substrate treating apparatus 1 with reference to FIG. 1 and the like. A carrier transport device, not shown, transports the carrier C to any of four carrier platforms 3. At this time, the substrate W is accommodated in the carrier C while the front face thereof is directed upwardly.

The indexer robot IR1 in the indexer block B1 takes a substrate W from the carrier C transported to the carrier platform 3, and transports the taken substrate W to the inversion unit RV1. The inversion unit RV1 inverses the substrate W to change the back face of the substrate W directed upward.

The back face of the substrate W is polished in the upper polishing layer 14A in the polishing block B2. The details of the back polishing in the polishing layer 14A is to be described later. The substrate transporting robot TR1 in the polishing layer 14A transports the substrate W, whose back face is polished, to the inversion unit RV3. Then, the inversion unit RV3 reverses the substrate W to change the front face of the substrate W directed upward.

Thereafter, in the upper coating layer 141A of the coating block B3, the substrate transporting robot TR2 takes the substrate W from the inversion unit RV3, and transports the substrate W to the cooling unit CP, the coating unit BARC, and the heat treating unit PAB in this order. At this time, the coating unit BARC forms an antireflection film on the front face of the substrate W. Then, the substrate transporting robot TR2 receives the substrate W from the heat treating unit PAB, and transports the substrate W to the cooling unit CP, the coating unit PR, the heat treating unit PAB, and the substrate buffer BF1 in this order. At this time, the coating unit PR coats the front face of the substrate W with the resist. Specifically, the coating unit PR forms a resist film on the antireflection film.

Thereafter, in the upper developing layer 153A of the developing block B4, the substrate transporting robot TR3 takes the substrate W from the substrate buffer BF1, and transports the substrate W to the edge exposing unit EEW and the substrate buffer BF3 in this order.

Thereafter, the substrate transporting robot TR4 of the IF block B5, for example, takes the substrate W from the substrate buffer BF3, and transports the substrate W to the back face cleaning unit BSS and the mounting-cum-cooling unit P-CP in this order. Thereafter, the substrate transporting robot TR6 in the IF block B5 takes the substrate W from the mounting-cum-cooling unit P-CP, and unloads the substrate W to the external exposure device EXP. Then, the exposure device EXP performs exposure treatment on the resist applied to the front face of the substrate W by emitting EUV-rays, for example. The back face of the substrate W is polished by the polishing unit 22 at this time, whereby the defocus drawback can be overcome.

Then, the substrate transporting robot TR6 of the IF block B5 loads the substrate W, on which the exposure treatment is performed, from the external exposure device EXP, and transports the substrate W to the substrate platform PS9. Then, the substrate transporting robot TR4, for example, takes the substrate W, on which the exposure treatment is performed, from the substrate platform PS9, and transports the substrate W to the post-exposure bake treatment unit PEB and the substrate buffer BF3 in this order. Here, the substrate transporting robot TR5 of the IF block B5 transports the substrate W in the same manner as the substrate transporting robot TR4 does.

Thereafter, in the developing layer 153A of the developing block B4, the substrate transporting robot TR3 takes the substrate W from the substrate buffer BF3, and transports the substrate W to the cooling unit CP, the developing unit DEV, the post-bake unit BP, and the substrate buffer BF1 in this order. At this time, the developing unit DEV performs developing treatment on the substrate W.

Thereafter, in the coating layer 141A of the coating block B3, the substrate transporting robot TR2 transports the substrate W from the substrate buffer BF1 to the substrate platform PS3. Thereafter, the substrate transporting robot TR1 in the polishing layer 14A of the polishing block B2 transports the substrate W from the substrate platform PS3 to the substrate platform PS1. Then, the indexer robot IR1 of the indexer block B1 receives the substrate W, on which the developing treatment is performed, from the substrate platform PS1, and returns the substrate W to the carrier C placed on the carrier platform 3. Thereafter, a carrier transport device, not shown, transports a carrier C for accommodating the treated substrate W into a next destination.

### (2-1) Operation of Polishing Block B2 (Polishing Layers 14A, 14B)

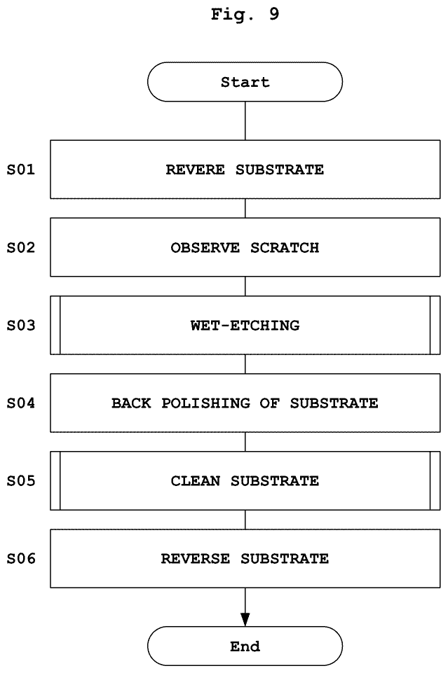

The following describes in detail back polishing in the polishing layer 14A of the polishing block B2 with reference to FIG. 9. Operation in the polishing layer 14B is similar to operation in the polishing layer 14A. The indexer robot IR1 in the indexer block B1 transports the substrate W to the inversion unit RV1. At this time, the device face of the substrate W is directed upward while the back face of the substrate W is directed downward.

### [Step S01] Reversing Substrate W

When one substrate W or two substrates W are placed on the mount members 137A, 137B by the indexer robot IR1, the inversion unit RV1 reverses one substrate W or two substrates W as shown in FIGS. 8(a) to 8(d). Accordingly, the back faces of the substrates W are each directed upward.

The substrate transporting robot TR1 takes the substrate W from the inversion unit RV1, and transports the substrate W to one of the two inspecting units 20. The substrate W whose back face is directed upward is placed on the stage 121 of the inspecting unit 20 shown in FIG. 7.

### [Step S02] Observing Scratch

The inspecting unit 20 performs inspection to the back face of the substrate W. The inspecting unit 20 detects a scratch, particles, and other projections. In this embodiment, description is particularly made of a case where a scratch formed on the back face of the substrate W is detected.

The lighting portion 125 emits light toward the back face of the substrate W in the inspecting unit 20 shown in FIG. 7. The camera 124 takes a picture of the back face of the substrate W to which light is emitted, thereby capturing an observed image. The camera 124 may take a picture while the XY-direction moving mechanism 122 moves the stage 121 on which the substrate W is placed. Large and small scratches appear in the captured observed image. The inspection controller 130 performs image processing on the observed image, and extracts one or more scratches to be polished where the reflected light is relatively strong, that is, part having luminance higher than a preset threshold. Moreover, the inspection controller 130 may extract a scratch to be polished based on a length of the scratch.

Moreover, the inspecting unit 20 measures a depth of a scratch when the scratch is detected. For example, when a plurality of scratches is detected (extracted), the inspecting unit 20 measures a depth of a representative scratch or depths of the representative scratches. The following describes measurement of the depth of the scratch.

The lifting mechanism 128 (FIG. 7) moves the laser microscope 127 downward to a preset height position. In addition, the XY-direction moving mechanism 122 moves the stage 121 in such a manner that a scratch to be measured is positioned below the objective lens 127A of the laser microscope 127. The stage 121 is moved in accordance with a coordinate of the scratch extracted in the observed image. The laser microscope 127 collects the reflected light through the objective lens 127A while irradiating the scratch (entirely or partially) and its periphery with laser light from the objective lens 127A. As a result, the laser microscope 127 captures a three-dimensional image containing a three-dimensional shape.

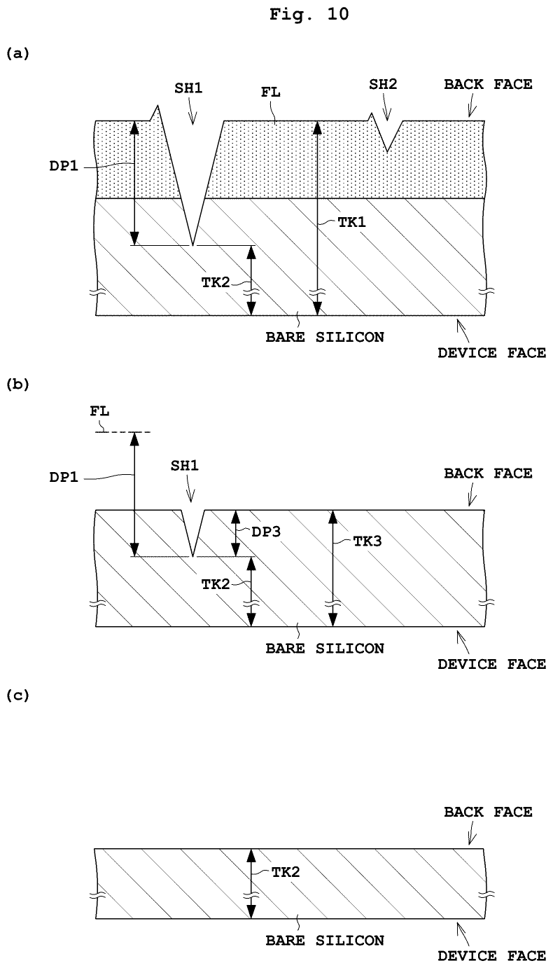

The inspection controller 130 measures a depth of the scratch by performing image processing to the three-dimensional image. FIG. 10(a) is a longitudinal sectional view for explanation of a state of the substrate W prior to an etching step. In FIG. 10(a), it is assumed that a thin film FL such as a silicon oxide film, a silicon nitride film, and polysilicon is formed on the back face of the substrate W. Moreover, it is assumed that a scratch SH1 on the left side of FIG. 10(a) reaches to bare silicon BSi. In this case, the inspection controller 130 measures a depth of the scratch SH1 (value DP1) from the three-dimensional image obtained by the laser microscope 127.

After the scratch and the like is observed, the substrate transporting robot TR1 transports the substrate W from the stage 121 of the inspecting unit 20 to any one of six polishing units 22 (U2 to U4). The substrate W whose back face is directed upward is placed on the holding rotator 35 of the polishing unit 22. Then, a magnet not shown causes three holding pins 43A shown in FIG. 5(a) to rotate around the rotary axis AX4. Thereby, the three holding pins 43A hold the substrate W. Here, the substrate W is held while being separated from the spin base 41 and the hot plate 45.

Here, the substrate thickness measuring device 39 measures the thickness of the substrate W prior to a next wet-etching step. A thickness TK1 of the substrate W as shown in FIG. 10(a) is obtained.

### [Step S03] Wet-Etching

When the thin film such as a silicon oxide film, a silicon nitride film, and polysilicon film is formed on the back face of the substrate W, the polisher 96 cannot polish the back face of the substrate W suitably. Some of these films are formed unintentionally in the manufacturing step of the device, while others are formed intentionally to suppress warping of the substrate W. Then, the polishing unit 22 removes a film FL formed on the back face of the substrate W by supplying a first chemical liquid (etching solution) to the back face of the substrate W.

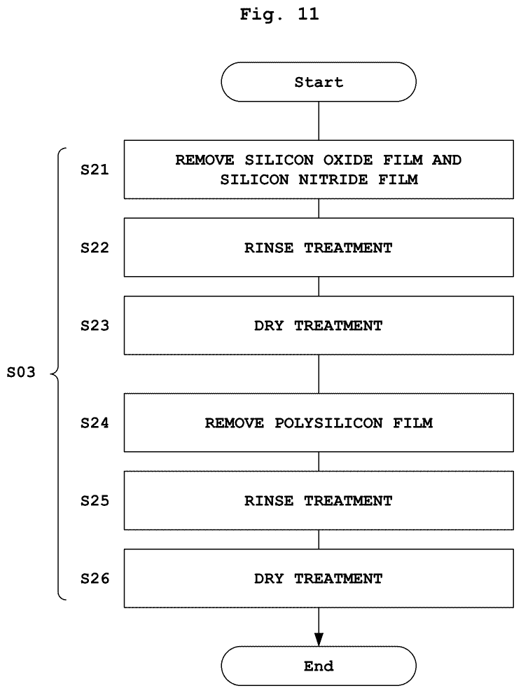

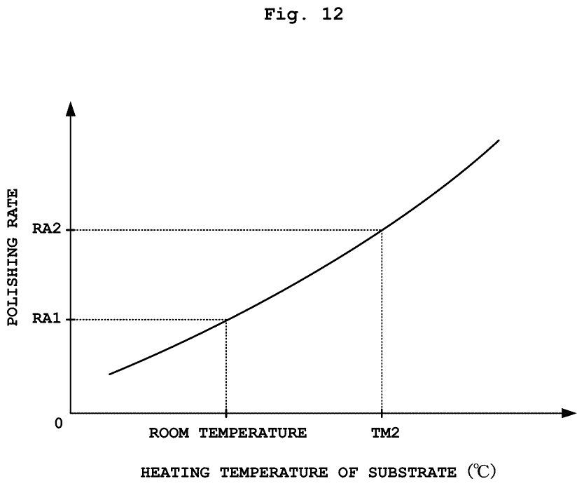

FIG. 11 is a flow chart for explanation of details of the wet-etching step in the step S03. Firstly, a silicon oxide film and a silicon nitride film are removed (step S21).

Here, the gas ejection port 47 provided at a center of the spin base 41 ejects gas. That is, the gas ejection port 47 ejects gas in such a manner that the gas flows in a gap between the substrate W and the spin base 41 from the center of the substrate W toward the outer edge of the substrate W. A device face (front face) of the substrate W faces the spin base 41. When gas is ejected from the gas ejection port 47, gas jets outward from the gap between an outer edge of the substrate W and the spin base 41. For example, the polishing scraps or a liquid such as the first chemical liquid can be prevented from adhering on the device face of the substrate W. That is, the device face can be protected. Moreover, due to a Bernoulli's effect, a force to absorb the substrate W to the spin base 41 acts.

The nozzle moving mechanism 95 moves the first chemical liquid nozzle 65 from a standby position outside of the substrate W to any treating position above the substrate W. The holding rotator 35 rotates the substrate W while holding the substrate W in a horizontal posture. Then, the first chemical liquid nozzle 65 supplies the first chemical liquid (e.g., hydrofluoric acid) to the back face of the rotating substrate W. Accordingly, the silicon oxide film and the silicon nitride film formed on the back face of the substrate W can be removed.

Here, the first chemical liquid may be supplied while the first chemical liquid nozzle 65 moves horizontally. Moreover, after the first chemical liquid nozzle 65 stops supply of the first chemical liquid, the first chemical liquid nozzle 65 is moved to the standby position outside of the substrate W.

Then, rinse treatment is performed (step S22). That is, the rinse liquid nozzle 73 supplies a rinse liquid (e.g., DIW or carbonated water) to the center of the rotating substrate W. In this way, the first chemical liquid remaining on the back face of the substrate W is washed off toward outside of the substrate. Then, dry treatment is performed (step S23). That is, the rinse liquid nozzle 73 stops supply of the rinse liquid. Then, the holding rotator 35 rotates the substrate W at high speed to dry the substrate W. At this time, the gas nozzle 75 moved above the substrate W may supply gas to the back face of the substrate W. Here, the dry treatment may be performed not by rotating the substrate W at high speed but by supplying gas from the gas nozzle 75.

After the steps S21 to S23, the polysilicon film is removed (step S24). The second chemical liquid nozzle 67 is moved from a standby position outside of the substrate W to any treating position above the substrate W. The holding rotator 35 rotates the substrate W at a preset rotation speed. Then, the second chemical liquid nozzle 67 supplies a second chemical liquid (e.g., a mixed liquid of hydrofluoric acid (HF) and nitric acid (HNO₃)) to the back face of the rotating substrate W. Accordingly, the polysilicon film formed on the back face of the substrate W can be removed.

The second chemical liquid may be supplied while the second chemical liquid nozzle 67 moves horizontally. Moreover, after the second chemical liquid nozzle 67 stops supply of the second chemical liquid, the second chemical liquid nozzle 67 is moved to the standby position outside of the substrate W.

Then, substantially similar to the case of the first chemical liquid (steps S22 and S23), rinse treatment (step S25) is performed and thereafter dry treatment (step S26) is performed. The holding rotator 35 stops rotation of the substrate W.

### [Step S04] Back Polishing of Substrate W

After the wet-etching step, the polishing unit 22 polishes the back face of the substrate W. Such polishing is performed especially when the inspecting unit 20 detects a scratch on the back face of the substrate W. Detailed description is as under.

The holding rotator 35 rotates the substrate W while holding the substrate W in a horizontal posture. The arm rotating mechanism 117 of the polishing mechanism 37 (FIG. 6) rotates the polisher 96 and the arm 101 around the vertical axis AX6. Accordingly, the polisher 96 is moved from the standby position outside of the substrate W to a preset position above the substrate W. Moreover, the electric motor 104 of the polishing mechanism 37 rotates the polisher 96 around the vertical axis AX5 (shaft 100).

Moreover, the hot plate 45 heats the substrate W with heat generated by passing current. The temperature sensor 46 of a non-contact type monitors a temperature of the substrate W. The main controller 165 adjusts heat from the hot plate 45 in accordance with the temperature of the substrate W detected by the temperature sensor 46. A heating temperature of the substrate W is adjusted to a temperature higher than room temperature (e.g., 25° C.) for obtaining a high polishing rate. Note that it is preferred to adjust the heating temperature to 100° C. or lower for avoiding thermal degradation of the polisher 96.

Then, the electropneumatic regulator 115 supplies gas, having pressure in accordance with the electrical signal, to the air cylinder 113. Accordingly, the air cylinder 113 moves the polisher 96 and the arm 101 downward to contact the polisher 96 against the back face of the rotating substrate W. The polisher 96 is pressed against the back face of the substrate W at preset contact pressure. This achieves polishing.

When the polishing is performed, the arm rotating mechanism 117 of the polishing mechanism 37 (FIG. 6) swings the polisher 96 and the arm 101 around the vertical axis AX6. That is, the polisher 96 reciprocates repeatedly between a position adjacent to the center of the back face and a position adjacent to the outer edge of the substrate W, for example.

Now; regarding an amount of polishing in the thickness direction (Z-direction) of the substrate W, it is considered unnecessary to perform polishing as long as the substrate W satisfies a preset flatness even if a scratch exists. However, an edge of the scratch may create a new damage on the stage of the exposure device, for example. Accordingly, polishing is performed until a scratch having a preset size is eliminated.

As shown in FIG. 10(a), the depth of the scratch SH1 (value DP1) is obtained by the laser microscope 127. Accordingly, the polishing unit 22 polishes the back face of the substrate W until a thickness corresponding to the depth of the scratch SH1 (value DP1), determined by the laser microscope 127, is scraped off. The thickness corresponding to the depth of the scratch SH1 is the value DP1. Polishing is performed until the thickness of the substrate W is brought into a value TK2 (=TK1−DP1). The thickness of the substrate W is periodically measured by the substrate thickness measuring device 39. When comparison is made between a measured value and a target value (e.g., value TK2) of the substrate thickness and then if the measured value does not reach the target value, the main controller 165 controls to perform polishing continuously.

Now, FIG. 10(b) is a view illustrating a state after the etching step (step S03). When the film FL is removed by the etching step, the depth of the scratch SH1 is decreased. Accordingly, an amount of polishing is made small in the up-down direction, whereas polishing is performed continuously until the thickness of the substrate W is brought into the value TK2. FIG. 10(c) is a view illustrating a state after the polishing step (step S04). Now; a scratch SH2 shown in FIG. 10(a) does not reach bare silicon. Such a scratch is removed together when the film FL such as silicon oxide film is removed.

The substrate W is heated by the hot plate 45. FIG. 12 illustrates a relationship between the heating temperature and the polishing rate of the substrate W. The contact pressure of the polisher 96, the rotation speed of the substrate W and the like are constant. Here, polishing rate increases when a temperature TM2 of the substrate W becomes high relative to a case where the temperature of the substrate W is room temperature (e.g., 25° C.), for example. Accordingly, heating the substrate W by hot plate 45 can increase the polishing rate. This can shorten time for polishing treatment.

When polishing is performed, the polishing unit 22 may adjust the polishing rate by controlling the heating temperature of the substrate W by the hot plate 45. Raising and lowering the heating temperature of the substrate W allow increase and decrease of the polishing rate. The polishing rate may be adjusted prior to or during the polishing. For example, the polishing rate can be made different between the part adjacent to the center of the substrate W and the part adjacent to the outer edge of the substrate W by changing the temperature of the substrate W between the part adjacent to the center of the substrate W and the part adjacent to the outer edge of the substrate W. Now, after polishing the back face of the substrate W, the polisher 96 is moved to the standby position out of the substrate W.

### [Step S05] Cleaning Substrate W

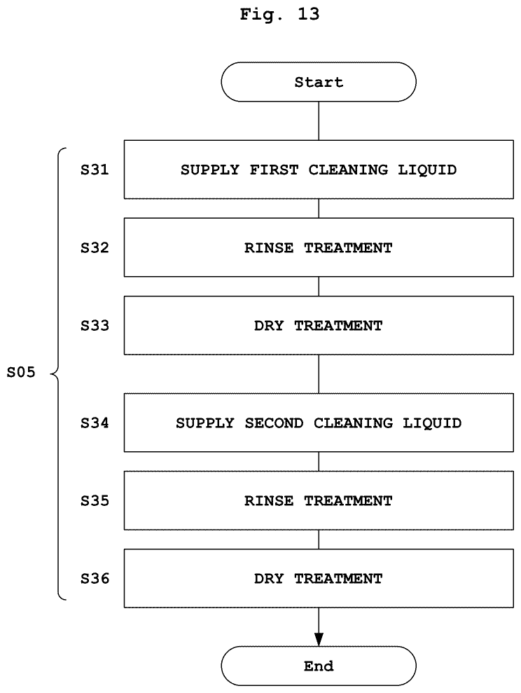

After the back face of the substrate W is polished, the back face of the substrate W is cleaned. Accordingly, polishing scraps (dust particles) remaining on the back face of the substrate W are removed, and metal, organic matters and particles are removed. FIG. 13 is a flow chart showing procedures of a cleaning step in the step S05.

Firstly, a first cleaning liquid is supplied to the back face of the substrate W (step S31). Detailed description is as under. The holding rotator 35 keeps holding of the substrate W. Moreover, the holding rotator 35 keeps protecting the device face of the substrate W by ejecting gas from the gas ejection port 47. The first cleaning liquid nozzle 69 is moved from a standby position outside of the substrate W to any treating position above the substrate W. The holding rotator 35 rotates the substrate W. Then, the first cleaning liquid nozzle 69 supplies the first cleaning liquid (e.g., SC2 or SPM) to the back face of the rotating substrate W. The first cleaning liquid may be supplied while the first cleaning liquid nozzle 69 moves horizontally.

After the first cleaning liquid is supplied to perform the cleaning treatment, rinse treatment is performed (step S32). That is, the rinse liquid nozzle 73 supplies a rinse liquid (DIW or carbonated water) to the center of the rotating substrate W. In this way; the first cleaning liquid remaining on the back face of the substrate W is washed off. Then, dry treatment is performed (step S33). That is, the rinse liquid nozzle 73 stops supply of the rinse liquid. Then, the holding rotator 35 rotates the substrate W at high speed to dry the substrate W. At this time, the gas nozzle 75 moved above the substrate W may supply gas to the back face of the substrate W. Here, the dry treatment may be performed not by rotating the substrate W at high speed but by supplying gas from the gas nozzle 75.

After the steps S31 to S33, a second cleaning liquid is supplied (step S34). That is, the second cleaning liquid nozzle 71 is moved from a standby position outside of the substrate W to any treating position above the substrate W. The holding rotator 35 rotates the substrate W at a preset rotation speed. Then, the second cleaning liquid nozzle 71 supplies the second cleaning liquid (e.g., SC1) to the back face of the rotating substrate W.

The second cleaning liquid may be supplied while the second cleaning liquid nozzle 71 moves horizontally. After the second cleaning liquid nozzle 71 stops supply of the second cleaning liquid, the second cleaning liquid nozzle 71 is moved to the standby position outside of the substrate W.

Then, substantially similar to the case of the first cleaning liquid (steps S32 and S33), rinse treatment (step S35) is performed and thereafter dry treatment (step S36) is performed. The holding rotator 35 stops rotation of the substrate W. Since the polishing unit 22 in this embodiment has a cleaning function, the substrate W from which polishing scraps are cleaned off can be unloaded from the polishing unit 22.

### [Step S06] Reversing Substrate W

The substrate transporting robot TR1 takes the substrate W from the polishing unit 22, and transports the substrate W to the inversion unit RV3. At this time, the back face of the substrate W is directed upward while the device face of the substrate W is directed downward. When one substrate W or two substrates W are placed on the mount members 137A, 137B by the substrate transporting robot TR1, the inversion unit RV3 reverses one substrate W or two substrates W as shown in FIGS. 8(a) to 8(d). Accordingly, the back faces of the substrates W are each directed downward.

Thereafter, the substrate transporting robot TR2 in the coating layer 141A takes the substrate W from the inversion unit RV3. The taken substrate W is coated with the resist in the coating layer 141A.

According to this embodiment, the polishing block B2, the coating block B3, and the developing block B4 are arranged horizontally in the substrate treating apparatus 1. The substrate treating apparatus 1 of this type includes the polishing unit 22 (holding rotator 35, polisher 96, and hot plate 45) and the coating unit PR. The polisher 96 has a resin body in which abrasive grains are distributed. The polisher 96 polishes the back face of the substrate W in the chemo-mechanical grinding (CMG) manner by contacting against the back face of the rotating substrate W. The substrate W is heated when the polishing is performed. When the substrate W is heated, a polishing rate can increase. This can shorten time for polishing treatment.

Moreover, with the polishing unit 22 and the coating unit PR, the resist is applied to the front face of the substrate W, and the polishing is performed to the back face of the substrate W. This achieves sufficient flatness of the substrate W to which the resist is applied, whereby the defocus drawback of the exposure device EXP can be overcome.

Moreover, the inspecting unit 20 for inspecting the substrate W detects a scratch formed on the back face of the substrate W before the back face of the substrate W is polished. Moreover, the polishing unit 22 polishes the back face of the substrate W when a scratch is detected. This can scrape the detected scratch, i.e., a selected scratch.

Moreover, the inspecting unit 20 measures a depth of a scratch when the scratch is detected. The polishing unit 22 polishes the back face of the substrate W until a thickness corresponding to the depth of the scratch measured by the inspecting unit 20 is scraped off. Accordingly, the depth of the scratch is recognized, achieving a suitable amount of polishing in a thickness direction of the substrate W.

Moreover, with the substrate treating apparatus 1, the polisher 96 polishes the back face of the substrate W in the chemo-mechanical grinding (CMG) manner by contacting against the back face of the rotating substrate W. Here, it is found that, when a film FL is formed on the back face of the substrate W, the polishing cannot be performed suitably due to the film FL. Then, the film FL formed on the back face of the substrate W is removed by etching treatment prior to polishing treatment. This can perform the polishing treatment suitably.

### SECOND EMBODIMENT

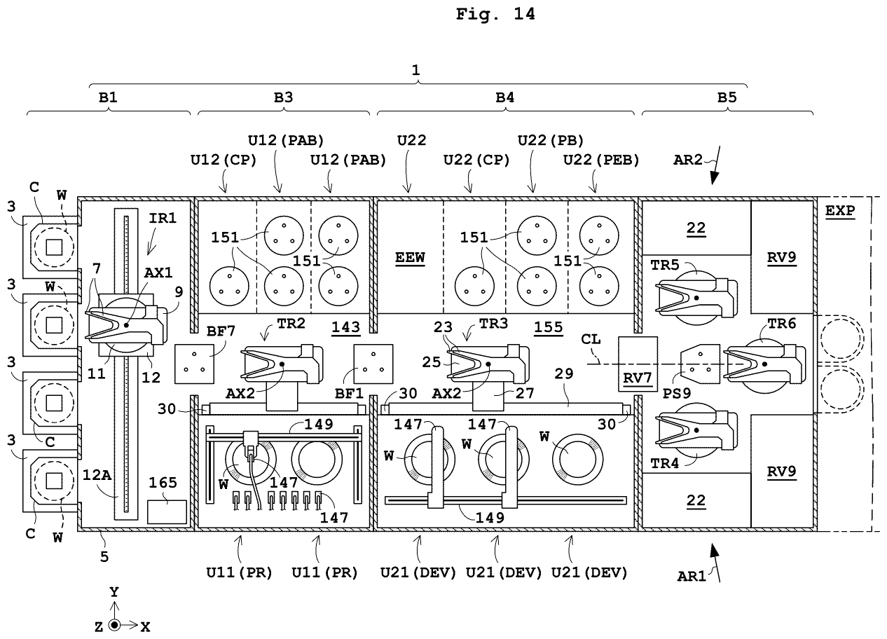

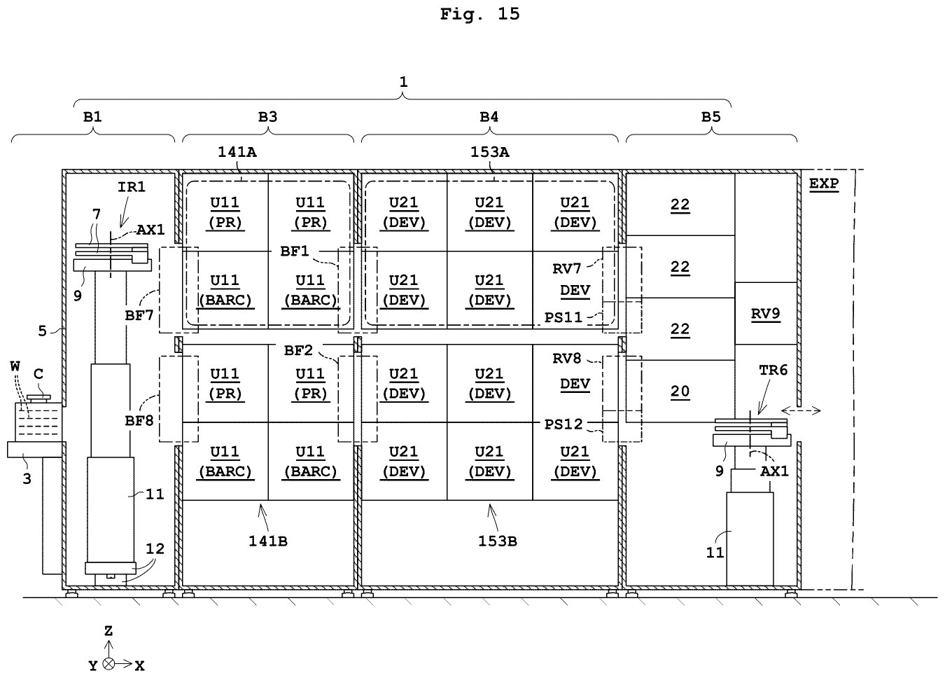

The following describes a second embodiment of the present invention with reference to the drawings. Here, the description common to that of the first embodiment is to be omitted. FIG. 14 is a horizontal cross-sectional view of a substrate treating apparatus 1 according to the second embodiment. FIG. 15 is a right side view of the substrate treating apparatus 1 according to the second embodiment.

In the first embodiment, the substrate treating apparatus 1 includes the polishing block B2 provided with the polishing unit 22. In this regard, in the second embodiment, the substrate treating apparatus 1 does not include a polishing block B2, and includes an IF block B5 provided with the polishing unit 22.

Reference is made to FIGS. 14 and 15. The substrate treating apparatus 1 includes an indexer block B1, a coating block B3, a developing block B4, and the IF block B5. The indexer block B1, the coating block B3, the developing block B4, and the IF block B5 are arranged horizontally and linearly in this order. The developing block B4 is located between the coating block B3 and the IF block B5. Here, the coating block B3 and the developing block B4 correspond to the treating block in the present invention.

Two developing layers 153A and 153B of the developing block B4 each include a plurality of post-exposure bake treatment units PEB as for the treating unit U22 in addition to a cooling unit CP, a post-bake unit PB, and an edge exposing unit EEW. Moreover, the substrate treating apparatus 1 includes four substrate buffers BF1, BF2, BF7, BF8, two inversion units RV7, RV8, and two substrate platforms PS11, PS12. The two inversion units RV7, RV8, and an inversion unit RV9, mentioned later, are configured in the same manner as the inversion unit RV1 shown in FIGS. 8(a) to 8(d).

The substrate buffer BF7 is located between the indexer block B1 and the upper coating layer 141A. The substrate buffer BF8 is located between the indexer block B1 and the lower coating layer 141B. Moreover, the inversion unit RV7 and the substrate platform PS11 are arranged between the upper developing layer 153A and the IF block B5. The inversion unit RV8 and the substrate platform PS12 are arranged between the lower developing layer 153B and the IF block B5.

The IF block B5 includes three substrate transporting robots TR4 to TR6, the substrate platform PS9, and three mounting-cum-cooling units P-CP. The IF block B5 further includes exemplarily two (plural) inspecting units 20, exemplarily six (plural) polishing units 22, and exemplarily two (plural) inversion units RV9. For example, a laminate formed by one inspecting unit 20 and three polishing units 22 is each arranged adjacent to the substrate transporting robot TR4 and the substrate transporting robot TR5.

It is assumed in FIG. 14 that there is a center line CL extending along a direction (X-direction) where the developing block B4 and the IF block B5 are arranged and passing through the center in a width direction of the apparatus 1 in a horizontal direction (Y-direction) orthogonal to the former direction. A first laminate like the polishing unit 22 on the side of arrow AR1 and the center line CL are arranged across the substrate transporting robot TR4. A second laminate like the polishing unit 22 on the side of arrow AR2 and the center line CL are arranged across the substrate transporting robot TR5.

The substrate transporting robot TR4 transports substrates W among the two inversion units RV7 and RV8, the inversion unit RV9 (on the side of arrow AR1), the three substrate platforms PS9, PS11, and PS12, the three mounting-cum-cooling units P-CP, the inspecting unit 20 (on the side of arrow AR1), and the three polishing units 22 (on the side of arrow AR1). Moreover, the substrate transporting robot TR5 transports substrates W among the two inversion units RV7 and RV8, the inversion unit RV9 (on the side of arrow AR2), the three substrate platforms PS9, PS11, and PS12, the three mounting-cum-cooling units P-CP, the inspecting unit 20 (on the side of arrow AR2), and the three polishing units 22 (on the side of arrow AR2).

### (3) Operation of Substrate Treating Apparatus 1

The following describes the operation of the substrate treating apparatus 1 of this embodiment with reference to FIGS. 14 and 15. The carrier C is placed on any of the four carrier platforms 3. At this time, the substrate W is accommodated in the carrier C while the front face thereof is directed upwardly.

The indexer robot IR1 in the indexer block B1 takes a substrate W from the carrier C, and transports the taken substrate W to the substrate buffer BF7, for example. Thereafter, in the upper coating layer 141A of the coating block B3, the substrate transporting robot TR2 takes the substrate W from the substrate buffer BF7, and transports the substrate W to the coating unit BARC, the coating unit PR and the like. Thereafter, the substrate transporting robot TR2 transports the substrate W, on which the antireflection film and the resist film are formed in this order, to the substrate buffer BF1.

Thereafter, in the upper developing layer 153A of the developing block B4, the substrate transporting robot TR3 takes the substrate W from the substrate buffer BF1, and transports the substrate W to the edge exposing unit EEW and the inversion unit RV7 in this order.

Thereafter, the substrate W is transported to the exposure device EXP via the IF block B5. Operation here is performed in accordance with the flow chart shown in FIG. 9. Detailed description is as under.

The inversion unit RV7 reverses the substrate W to change the back face of the substrate W directed upward (step S01). Thereafter, in the IF block B5, the substrate transporting robot TR4, for example, takes the substrate W from the inversion unit RV7, and transports the substrate W to the inspecting unit 20, the polishing unit 22, and the inversion unit RV9 in this order. Here, the inspecting unit 20 detects a scratch on the back face of the substrate W and measures a depth of the scratch (step S02). Thereafter, the polishing unit 22 performs wet etching treatment on the back face of the substrate W (step S03).

Thereafter, the polishing unit 22 polishes the back face of the substrate W in a chemo-mechanical grinding manner (CMG) by contacting the polisher 96 against the rotating substrate W while the hot plate 45 heats the substrate W (step S04). Back polishing is performed in accordance with the depth of the scratch until the scratch is scraped off. Then, the polishing unit 22 cleans the back face of the substrate W (step S05). Then, the inversion unit RV9 reverses the substrate to change the front face of the substrate W directed upward (step S06). The substrate transporting robot TR4 transports the substrate W, whose front face is directed upward, from the inversion unit RV9 to the mounting-cum-cooling unit P-CP.

Thereafter, the substrate transporting robot TR6 in the IF block B5 takes the substrate W from the mounting-cum-cooling unit P-CP, and unloads the substrate W to the external exposure device EXP. Then, the exposure device EXP performs exposure treatment on the resist applied to the front face of the substrate W by emitting EUV-rays, for example.

Then, the substrate transporting robot TR6 in the IF block B5 loads the substrate W, on which the exposure treatment is performed, from the external exposure device EXP, and transports the substrate W to the substrate platform PS9. Then, the substrate transporting robot TR4, for example, transports the substrate W, on which the exposure treatment is performed, from the substrate platform PS9 to the substrate platform PS11, for example.

Thereafter, in the developing layer 153A in the developing block B4, the substrate transporting robot TR3 takes the substrate W from the substrate platform PS11, and transports the substrate W to the post-exposure bake treatment unit PEB, the cooling unit CP, the developing unit DEV, the post-bake unit BP, and the substrate buffer BF1 in this order.

Thereafter, in the coating layer 141A of the coating block B3, the substrate transporting robot TR2 transports the substrate W from the substrate buffer BF1 to the substrate buffer BF7. Then, the indexer robot IR1 in the indexer block B1 receives the substrate W, on which the developing treatment is performed, from the substrate buffer BF7, and returns the substrate W to the carrier C placed on the carrier platform 3.

This embodiment produces the same effect as that of the first embodiment. That is, the coating block B3, the developing block B4, and the IF block B5 are arranged horizontally in the substrate treating apparatus 1. In the substrate treating apparatus 1 of this type, the IF block B5 includes the polishing unit 22 (holding rotator 35, polisher 96, and hot plate 45). Moreover, the coating block B3 includes the coating unit PR. The polisher 96 has a resin body in which abrasive grains are distributed. The polisher 96 polishes the back face of the substrate W in the chemo-mechanical grinding (CMG) manner by contacting against the back face of the rotating substrate W. The substrate W is heated when the polishing is performed. When the substrate W is heated, a polishing rate can increase. This can shorten time for polishing treatment.

Moreover, with the polishing unit 22 and the coating unit PR, the resist is applied to the front face of the substrate W, and the polishing is performed to the back face of the substrate W. This achieves sufficient flatness of the substrate W to which the resist is applied, whereby the defocus drawback of the exposure device EXP can be overcome.

### THIRD EMBODIMENT

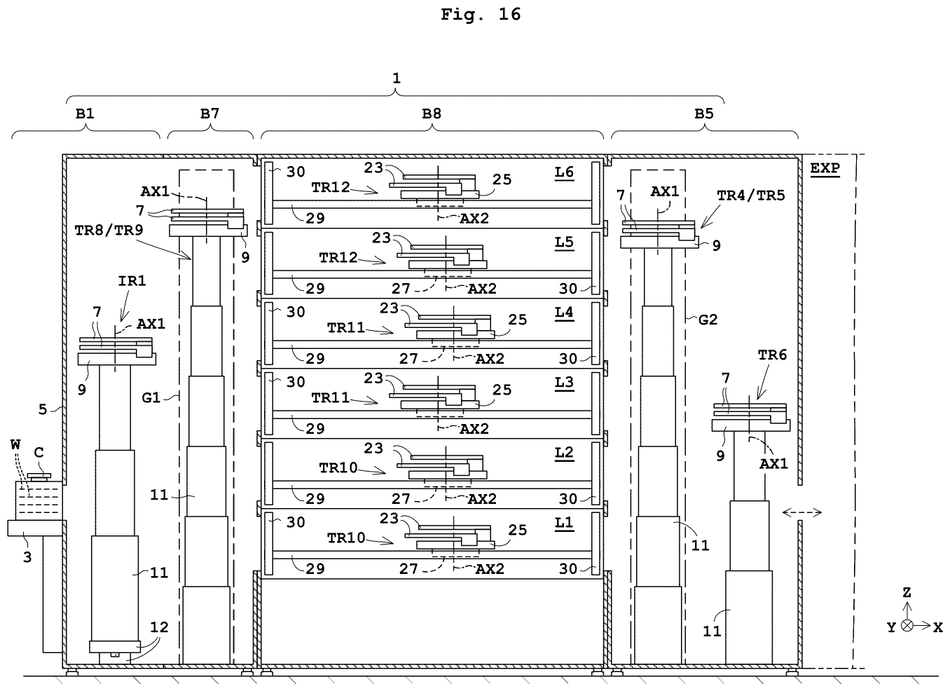

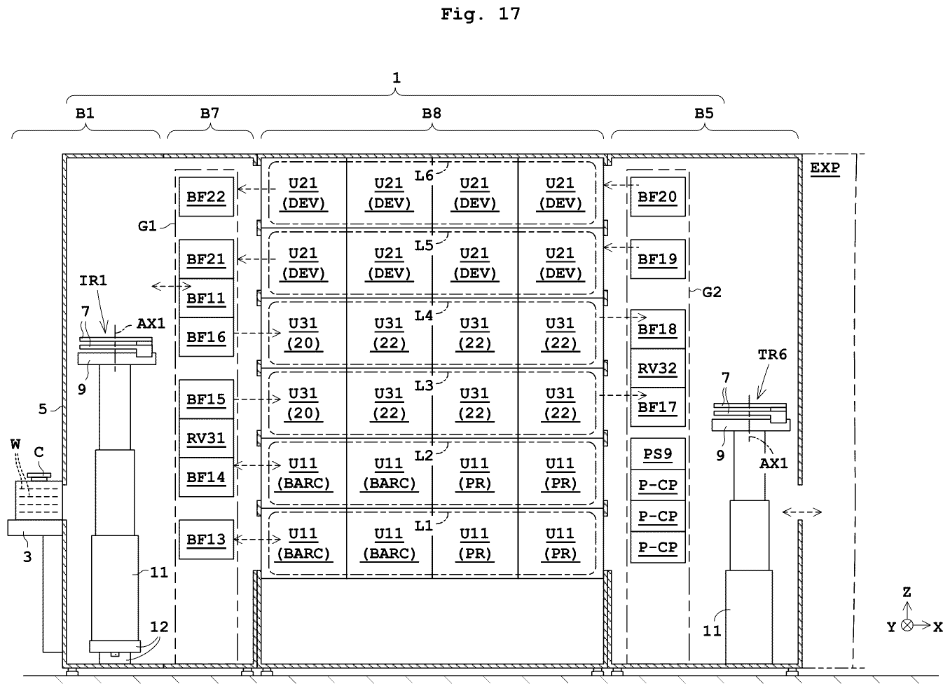

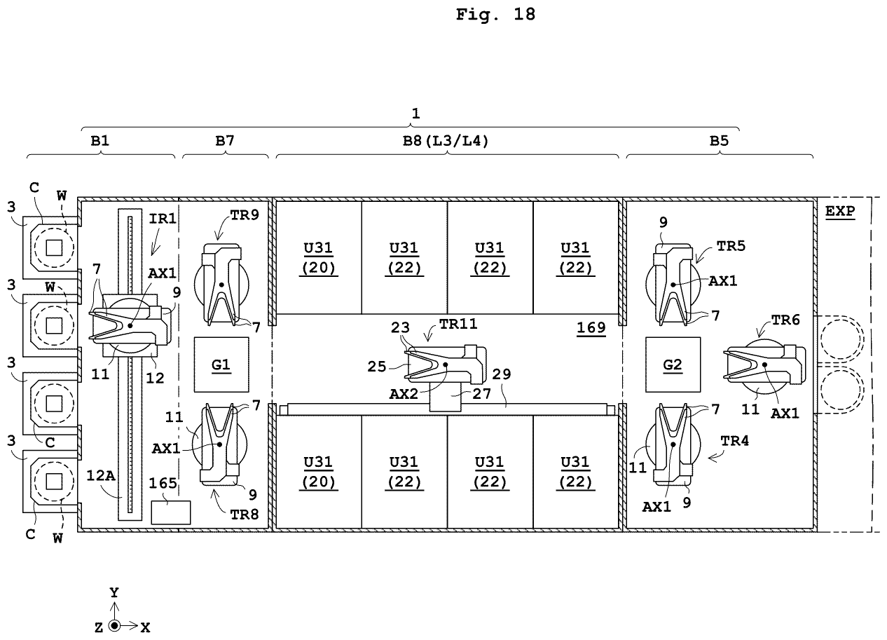

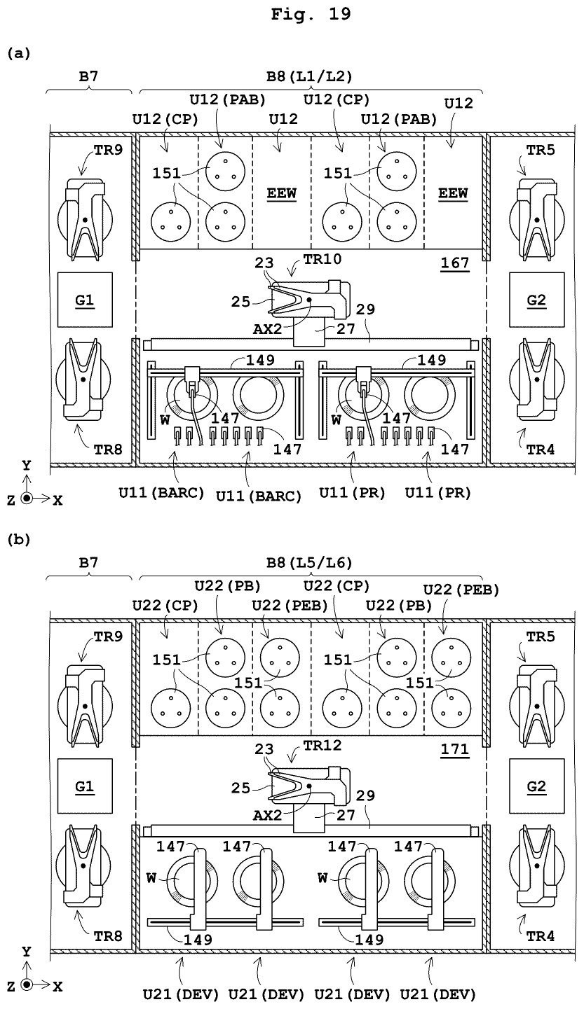

The following describes a third embodiment of the present invention with reference to the drawings. Here, the description common to that of the first and second embodiments is to be omitted. FIG. 16 is a longitudinal cross-sectional view of a substrate treating apparatus 1 according to the third embodiment. FIG. 17 is a right side view of the substrate treating apparatus 1 according to the third embodiment. FIG. 18 is a horizontal cross-sectional view of the substrate treating apparatus 1 (e.g., polishing layer L3) according to the third embodiment. FIG. 19(a) is a transverse cross-sectional view of a coating layer L1 according to the third embodiment. FIG. 19(b) is a transverse cross-sectional view of a developing layer L5 according to the third embodiment.

In the first embodiment, the polishing block B2, the coating block B3, and the developing block B4 are arranged horizontally in a row. In this regard, coating layers L1, L2, polishing layers L3, L4, and developing layers L5, L6 are stacked in the up-down direction in a single treating block B8 in the third embodiment.

### (4) Construction of Substrate Treating Apparatus 1

Reference is made to FIGS. 16 to 18. The substrate treating apparatus 1 includes an indexer block B1, an intermediate block B7, a treating block B8, and an IF block B5. The indexer block B1, the intermediate block B7, the treating block B8, and the IF block B5 are arranged horizontally and linearly in this order.

### (4-1) Construction of Indexer Block B1

The indexer block B1 is configured in substantially the same manner as the indexer block B1 in the first embodiment. The indexer block B1 includes, for example, four (plural) carrier platforms 3 and an indexer robot IR1. The indexer robot IR1 loads and unloads substrates W, placed on the carrier platform 3, to and from the carrier C. Moreover, the indexer robot IR1 transports the substrates W between the carriers C each placed on the carrier platforms 3 and a substrate buffer BF11, mentioned later. Moreover, the indexer robot IR1 transports the substrates W to and from the treating block B8 via a buffer group G1 (containing the substrate buffer BF11), mentioned later.

### (4-2) Construction of Intermediate Block B7

The intermediate block B7 includes the buffer group G1 in a tower shape, and two substrate transporting robots TR8, TR9 (see FIG. 18). The buffer group G1 is located between the two substrate transporting robots TR8, TR9 in plan view (see FIG. 18). Moreover, the buffer group G1 is located between the indexer robot IR1 and transportation spaces 167, 169, 171 mentioned later in plan view.

The buffer group G1 includes seven substrate buffers BF11, BF13, BF14, BF15, BF16, BF21, BF22, and an inversion unit RV31 (see FIG. 17). These are arranged in the up-down direction. The seven substrate buffers BF11, BF13 to BF16, BF21, and BF22 each have one or more substrates W placed thereon. The inversion unit RV31 and an inversion unit RV32, mentioned later, are configured in the same manner as the inversion unit RV1 shown in FIGS. 8(a) to 8(d).

The two substrate transporting robots TR8, TR9 are configured in the same manner as the substrate transporting robot TR4 in the IF block B5, for example. Moreover, the two substrate transporting robots TR8, TR9 are each capable of transporting a substrate W among the seven substrate buffers BF11, BF13, BF14, BF15, BF16, BF21, BF22, and the inversion unit RV31.

### (4-3) Construction of Treating Block B8

In the treating block B8, a predetermined treatment is performed on the substrates W. The treating block B8 includes exemplary six (plural) treatment layers L1 to L6. That is, the treating block B8 includes two coating layers L1, L2, two polishing layers L3, L4, and two developing layers L5, L6. These six treatment layers L1 to L6 are arranged in the up-down direction. The coating layer L1 is configured in the same manner as the coating layer L2. The polishing layer L3 is configured in the same manner as the polishing layer L4. The developing layer L5 is configured in the same manner as the developing layer L6. Accordingly, the coating layer L1, the polishing layer L3, and the developing layer L5 will be described as representative examples.

### (4-3-1) Construction of Coating Layer L1 (L2)

Reference is now made to FIG. 19(a). The coating layer L1 includes a transportation space 167, a substrate transporting robot TR10, liquid treating units U11, and treating units U12. The substrate transporting robot TR10 is located in the transportation space 167. Moreover, the substrate transporting robot TR10 and substrate transporting robots TR11, TR12, which are to be mentioned later, are constructed in the same manner as the substrate transporting robot TR1 shown in FIG. 1.

Reference is now made to FIGS. 17 and 19 (a). The substrate transporting robot TR10 in the coating layer L1 transports substrates W among the substrate buffer BF13, exemplary four (plural) liquid treating units U11 (in the coating layer L1), and a plurality of treating units U12 (in the coating layer L1). Moreover, the substrate transporting robot TR10 in the coating layer L2 transports substrates W among the substrate buffer BF14, exemplary four (plural) liquid treating units U11 (in the coating layer L2), and a plurality of treating units U12 (in the coating layer L2).

As the liquid treating unit U11, a coating unit PR configured to coat a front face of the substrate W with the resist, for example (see FIG. 17). In addition, as for the liquid treating unit U11, a coating unit BARC configured to form (apply) an antireflection film may be used, for example. As for the treating unit U12, a cooling unit CP, a heat treating unit PAB, and an edge exposing unit EEW are used, for example (see FIG. 19(a)).

### (4-3-2) Construction of Polishing Layer L3 (L4)

Reference is made to FIG. 18. The polishing layer L3 includes a transportation space 169, a substrate transporting robot TR11, and eight (plural) treating units U31. The substrate transporting robot TR11 is located in the transportation space 169.

Reference is made to FIGS. 17 and 18. The substrate transporting robot TR11 in the polishing layer L3 transports a substrate W between the two substrate buffers BF15, BF17 and eight treating units U31 (in the polishing layer L3). Moreover, the substrate transporting robot TR11 in the polishing layer L4 transports a substrate W between the two substrate buffers BF16, BF18 and eight treating units U31 (in the polishing layer L4). Two inspecting units 20 and six polishing units 22 are used as the eight treating units U31.

### (4-3-3) Construction of Developing Layer L5(L6)

Reference is now made to FIG. 19(b). The developing layer L5 includes a transportation space 171, a substrate transporting robot TR12, exemplarily four (plural) liquid treating units U21, and a plurality of treating units U22. The substrate transporting robot TR12 is located in the transportation space 171.

Reference is now made to FIGS. 17 and 19 (b). The substrate transporting robot TR12 in the developing layer L5 transports substrates W among the two substrate buffers BF19, BF21, the four liquid treating units U21 (in the developing layer L5), and the treating units U22 (in the developing layer L5). Moreover, the substrate transporting robot TR12 in the developing layer L6 transports substrates W among the two substrate buffers BF20, BF22, the four liquid treating units U21 (in the developing layer L6), and the treating units U22 (in the developing layer L6).

A developing unit DEV is used as the liquid treating unit U21. Moreover, as for the treating unit U22, a post-exposure bake treatment unit PEB, a cooling unit CP and a post-bake unit PB are used, for example.

### (4-4) Construction of IF Block B5

Reference is made to FIGS. 16 to 18. The IF block B5 includes a buffer group G2 in a tower shape in addition to the three substrate transporting robots TR4 to TR6. The buffer group G2 is located between the two substrate transporting robots TR4, TR5 in plan view. Moreover, the buffer group G2 is located between the transportation spaces 167, 169, 171 and the substrate transporting robot TR6 in plan view.

The buffer group G2 includes four substrate buffers BF17, BF18, BF19, BF20, an inversion unit RV32, a substrate platform PS9, and three mounting-cum-cooling units P-CP (see FIG. 17). These are arranged in the up-down direction. The four substrate buffers BF17 to BF20 each have one or more substrates W placed thereon.

The two substrate transporting robots TR4, TR5 are each capable of transporting a substrate W among the four substrate buffers BF17, BF18, BF19, BF20, the inversion unit RV32, the substrate platform PS9, and the three mounting-cum-cooling units P-CP. Moreover, the substrate transporting robot TR6 is capable of transporting the substrate W among the exposure device EXP, the substrate platform PS9, and the three mounting-cum-cooling units P-CP.

### (5) Operation of Substrate Treating Apparatus 1

The following describes the operation of the substrate treating apparatus 1 of the third embodiment with reference to FIGS. 16 and 19 (b). The carrier C is placed on any of the four carrier platforms 3. At this time, the substrate W is accommodated in the carrier C while the front face thereof is directed upwardly.

The indexer robot IR1 in the indexer block B1 takes a substrate W from the carrier C placed on the platform 3, and transports the taken substrate W to the substrate buffer BF11 in the buffer group G1, for example. In the intermediate block B7, one of the two substrate transporting robots TR8, TR9 transports the substrate W from the substrate buffer BF11 to the substrate buffer BF13 (or the substrate buffer BF14) (see FIGS. 17 and 18). Here in this description, the substrate transporting robot TR8 performs substrate transportation in the intermediate block B7.

The substrate transporting robot TR10 in the lower coating layer L1 takes a substrate W from the substrate buffer BF13, and transports the substrate W to the cooling unit CP, the coating unit BARC, and the heat treating unit PAB in this order. Then, the substrate transporting robot TR10 takes the substrate W from the heat treating unit PAB, and transports the substrate W to the cooling unit CP, the coating unit PR, the heat treating unit PAB, the edge exposing unit EEW, and the substrate buffer BF13 in this order.

Note that, if the substrate transporting robot TR8 transports the substrate W to the substrate buffer BF14, the front face of the substrate W is coated with the resist in the upper coating layer L2 in the same manner as that in the lower coating layer L1. The substrate W coated with the resist in the coating layer L2 is transported to the substrate buffer BF14.

In the intermediate block B7, the substrate transporting robot TR8 transports the substrate W, coated with the resist, from the substrate buffer BF13 (or the substrate buffer BF14) to the inversion unit RV31. Then, the inversion unit RV31 reverses the substrate W to change the back face of the substrate W directed upward. Then, the substrate transporting robot TR8 transports the substrate W from the inversion unit RV31 to the substrate buffer BF15 (or substrate buffer BF16).

Then, in the polishing layer L3 (L4), operation from the step S02 (observing scratch) to the step S05 (cleaning substrate) in the flow chart of FIG. 9 is performed. The following schematically describes the operation. The substrate transporting robot TR11 in the lower polishing layer L3 takes the substrate W from the substrate buffer BF15, and transports the substrate W to the inspecting unit 20 and the polishing unit 22 in this order. At this time, the inspecting unit 20 detects a scratch on the back face of the substrate W and measures a depth of the scratch (step S02). Thereafter, the polishing unit 22 performs wet etching treatment on the back face of the substrate W (step S03).

Thereafter, the polishing unit 22 polishes the back face of the substrate W in a chemo-mechanical grinding (CMG) manner by contacting the polisher 96 against the rotating substrate W while the hot plate 45 heats the substrate W (step S04). Back polishing is performed in accordance with the depth of the scratch until the scratch is scraped off. Then, the polishing unit 22 cleans the back face of the substrate W (step S05). Thereafter, the substrate transporting robot TR11 in the lower polishing layer L3 takes the substrate W from the polishing unit 22, and transports the substrate W to the substrate buffer BF17 in the buffer group G2.

Note that, if the substrate transporting robot TR8 transports the substrate W to the substrate buffer BF16, the back face of the substrate W is polished in the upper polishing layer L4 in the same manner as that in the lower polishing layer L3. The substrate W whose back face is polished in the polishing layer L4 is transported to the substrate buffer BF18 in the buffer group G2.

Thereafter, in the IF block B5, one of the two substrate transporting robots TR4, TR5 transports the substrate W from the substrate buffer BF17 (or substrate buffer BF18) to the inversion unit RV32. Here in this explanation, the substrate transporting robot TR4 performs substrate transportation in two levels in the buffer group G2. The inversion unit RV32 reverses the substrate W to change the front face of the substrate W directed upward. Then, the substrate transporting robot TR4 transports the substrate W, whose front face is directed upward, from the inversion unit RV32 to any of the three mounting-cum-cooling units P-CP.

Thereafter, the substrate transporting robot TR6 in the IF block B5 takes the substrate W from the mounting-cum-cooling unit P-CP, and unloads the substrate W to the external exposure device EXP. The exposure device EXP performs the exposure treatment on the substrate W. Then, the substrate transporting robot TR6 loads the substrate W, on which the exposure treatment is performed by the exposure device EXP, and transports the substrate W to the substrate platform PS9. Thereafter, the substrate transporting robot TR4 in the IF block B5 transports the substrate W from the substrate platform PS9 to the substrate buffer BF19 (or substrate buffer BF20).

Thereafter, in the lower developing layer L5, the substrate transporting robot TR12 takes the substrate W from the substrate buffer BF19, and transports the substrate W to the post-exposure bake treatment unit PEB, the cooling unit CP, the developing unit DEV, the post-bake unit PB, and the substrate buffer BF21 in this order.

Note that, if the substrate transporting robot TR4 transports the substrate W to the substrate buffer BF20, the developing treatment is performed to the substrate W in the upper developing layer L6 in the same manner as that in the lower developing layer L5. The substrate W subjected to the developing treatment in the developing layer L6 is transported to the substrate buffer BF22.

Thereafter, in the intermediate block B7, the substrate transporting robot TR8 transports the substrate W from the substrate buffer BF21 (or substrate buffer BF22) to the substrate buffer BF11. Then, the indexer robot IR1 in the indexer block B1 takes the substrate W from the substrate buffer BF11, and returns the substrate W to the carrier C placed on the carrier platform 3.

This embodiment produces the same effect as that of the first embodiment. That is, in the treating block B8 of the substrate treating apparatus 1, the polishing layers L3, L4, the coating layers L1, L2, and the developing layers L5, L6 are stacked in the up-down direction. The substrate treating apparatus 1 of this type includes the polishing unit 22 (holding rotator 35, polisher 96, and hot plate 45) and the coating unit PR. The polisher 96 has a resin body in which abrasive grains are distributed. The polisher 96 polishes the back face of the substrate W in the chemo-mechanical grinding (CMG) manner by contacting against the back face of the rotating substrate W. The substrate W is heated when the polishing is performed. When the substrate W is heated, a polishing rate can increase. This can shorten time for polishing treatment.

Moreover, with the polishing unit 22 and the coating unit PR, the resist is applied to the front face of the substrate W, and the polishing is performed to the back face of the substrate W. This achieves sufficient flatness of the substrate W to which the resist is applied, whereby the defocus drawback of the exposure device EXP can be overcome.

Moreover, the intermediate block B7 is located between the indexer block B1 and the treating block B8. The intermediate block B7 includes the buffer group G1, and the two substrate transporting robots TR8, TR9. The buffer group G1 includes a plurality of substrate buffers (e.g., by numerals BF13, BF15) arranged in the up-down direction.

The two substrate transporting robots TR8, TR9 are each capable of transporting the substrate W among the substrate buffers (e.g., by numerals BF13, BF15) in the buffer group G1, achieving efficient transportation of the substrate W on a side adjacent to the indexer block B1.

### (6) Modification of Third Embodiment

In the above description, the substrate W is transported to the coating layer L1 (L2), and then is transported to the polishing layer L3 (L4). Accordingly, the back face of the substrate W coated with the resist in the coating layer L1 (L2) is polished in the polishing layer L3 (L4). In this regard, the substrate W may be transported to the coating layer L1 (L2) after being transported to the polishing layer L3 (L4). Accordingly, the front face of the substrate W, whose back face is polished in the polishing layer L3 (L4), is coated with the resist in the coating layer L1 (L2). In this case, the arrangement and the number of the substrate buffer (e.g., by numeral BF13) and the inversion units RV31, RV32 are changed appropriately.

Moreover, in the above description, the treating block B8 includes the two polishing layers L3, L4. In this regard, as shown in FIGS. 14 and 15, the polishing unit 22 may be provided in the IF block B5. The order of stacking the treatment layers L1 to L6 is variable appropriately.

Moreover, in the above description, the intermediate block B7 includes the two substrate transporting robots TR8, TR9, as shown in FIG. 18. In this regard, the intermediate block B7 may include only one of the two substrate transporting robots TR8, TR9.

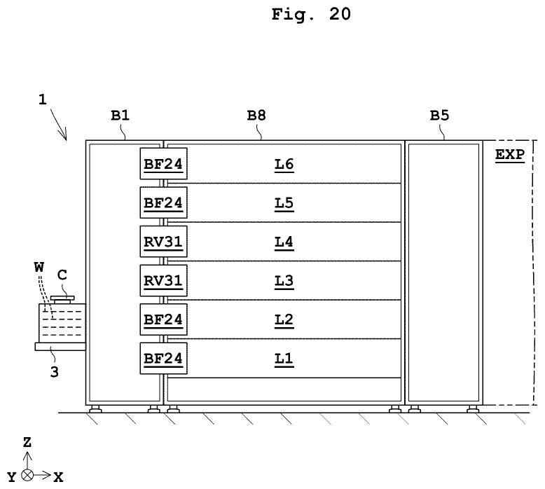

Moreover, in the above description, the intermediate block B7 is located between the indexer block B1 and the treating block B8, as shown in FIG. 16. In this regard, the indexer block B1 may be connected directly to the treating block B8, as shown in FIG. 20. In this case, substrate buffers BF24 is provided between the indexer block B1 and each of the four treatment layers L1, L2, L5, L6, for example. Moreover, the inversion units RV31 may be provided between the indexer block B1 and the two polishing layers L3, L4.

### FOURTH EMBODIMENT

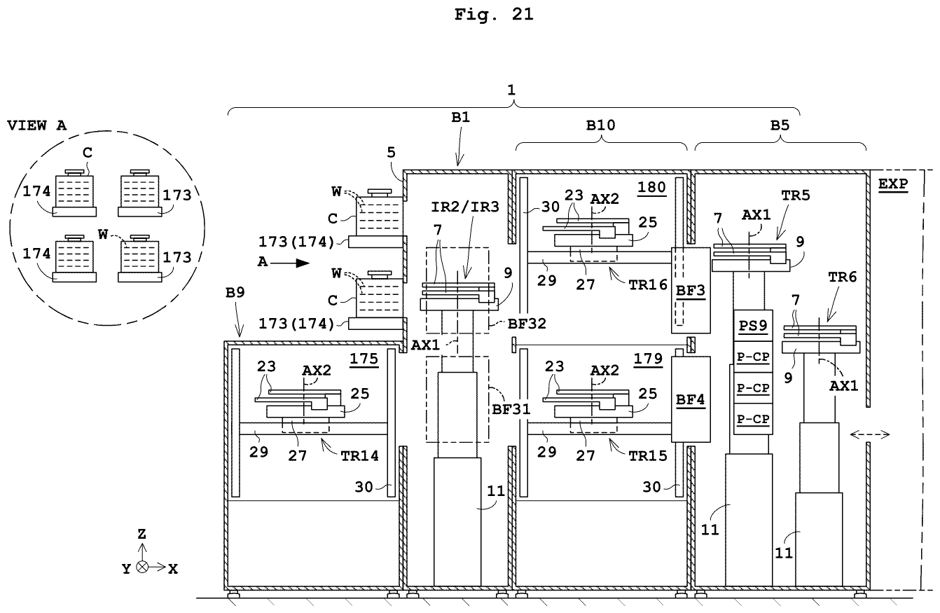

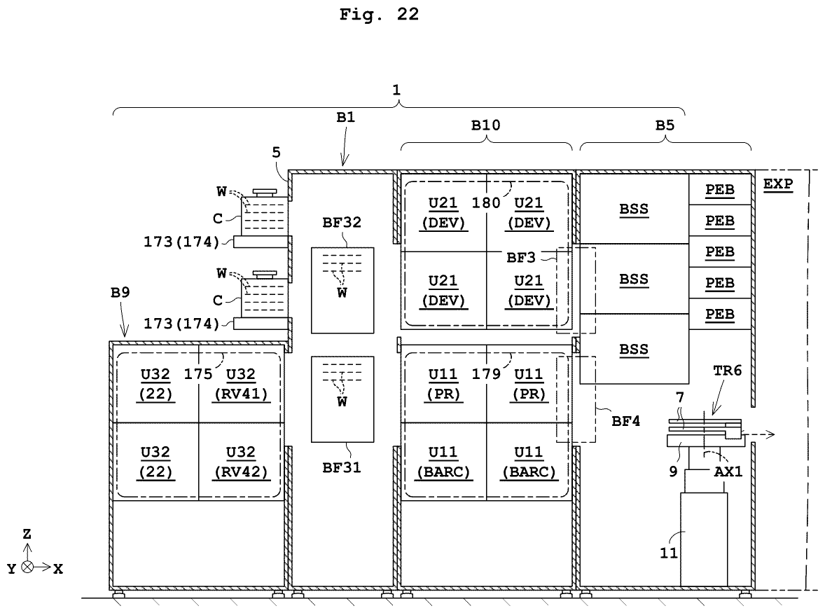

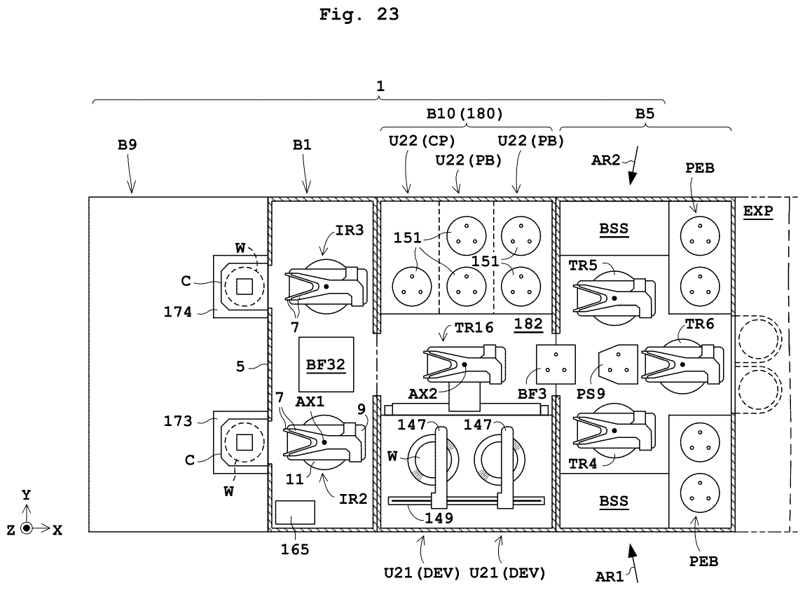

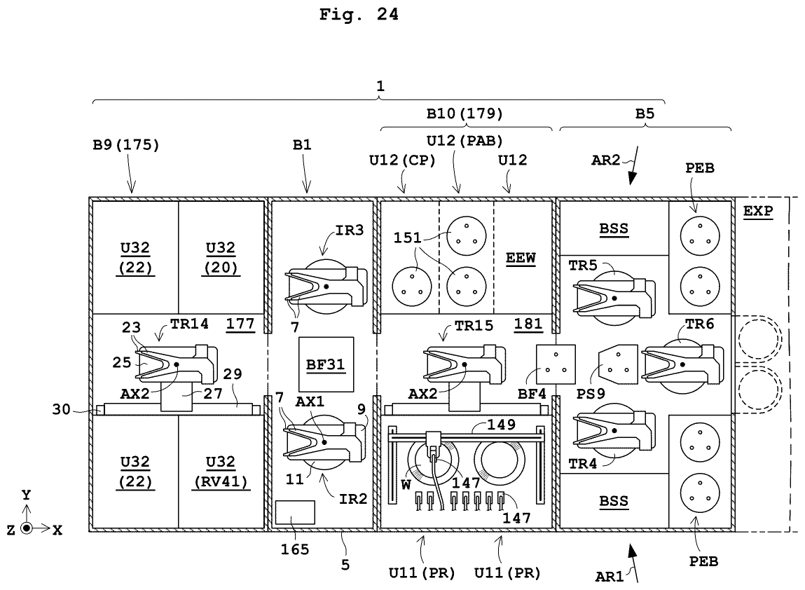

A fourth embodiment of the present invention will now be described with reference to the drawings. Here, the description common to that of the first to third embodiments is to be omitted. FIG. 21 is a longitudinal cross-sectional view of a substrate treating apparatus 1 according to the fourth embodiment. FIG. 22 is a right side view of the substrate treating apparatus 1 according to the fourth embodiment. FIG. 23 is a horizontal cross-sectional view of an upper layer of the substrate treating apparatus 1 according to the fourth embodiment. FIG. 24 is a horizontal cross-sectional view of a lower layer of the substrate treating apparatus 1 according to the fourth embodiment.

In the first embodiment, the treating blocks (the polishing block B2, the coating block B3, and the developing block B4) are arranged between the indexer block B1 and the IF block B5. In this regard, in the fourth embodiment, a first treating block B9 and a second treating block B10 are arranged across the indexer block B1.

### (7) Construction of Substrate Treating Apparatus 1

Reference is made to FIGS. 21 to 24. The substrate treating apparatus 1 includes the indexer block B1, a first treating block B9, a second treating block B10, and an IF block B5. The first treating block B9, the indexer block B1, the second treating block B10, and the IF block B5 are arranged horizontally and linearly in this order.

### (7-1) Construction of Indexer Block B1

The indexer block B1 includes four carrier platforms 173, 174, two substrate buffers BF31, BF32, and two indexer robots IR2, IR3. The four carrier platforms 173, 174 are arranged in two stages in the up-down direction (Z-direction), each stage having two carrier platforms in the horizontal direction (Y-direction). The four carrier platforms 173, 174 are arranged on an outer side face of a housing 5. Moreover, the four carrier platforms 173, 174 are located above the first treating block B9.

The two substrate buffers BF31, BF32 each have one or more substrates W placed thereon. The two substrate buffers BF31, BF32 are arranged in an up-down direction. The two substrate buffers BF31, BF32 are arranged inside of the housing 5.

The two indexer robots IR2, IR3 are arranged side by side in the Y-direction. The two indexer robots IR2, IR3 are each configured in the same manner as the substrate transporting robot TR4. The two indexer robots IR2, IR3 each load and unload substrates W to and from carriers C placed on the carrier platforms 173, 174.

Moreover, the indexer robot IR2 transports a substrate W between the carriers C placed on the two carrier platforms 173 and the two substrate buffers BF31, BF32. In contrast to this, the indexer robot IR3 transports a substrate W between the carriers C placed on the two carrier platforms 174 and the two substrate buffers BF31, BF32.

### (7-2) Construction of First Treating Block B9

The first treating block B9 includes one polishing layer 175. The polishing layer 175 includes a transportation space 177, a substrate transporting robot TR14, and exemplary eight (plural) treating units U32.

The substrate transporting robot TR14 is located in the transportation space 177. The substrate transporting robot TR14 and two substrate transporting robots TR15, TR16, which are to be mentioned later, are constructed in the same manner as the substrate transporting robot TR1 shown in FIG. 1. The substrate transporting robot TR14 transports a substrate W among the substrate buffer BF31 and the eight treating units U32. For example, two inversion units RV41, RV42, two inspecting units 20 and four polishing units 22 are used as the eight treating units U32. The inversion units RV41, RV42 are each configured in the same manner as the inversion unit RV1 shown in FIGS. 8(a) to 8(d).

### (7-3) Construction of Second Treating Block B10

The second treating block B10 includes a coating layer 179 and a developing layer 180. The coating layer 179 and the developing layer 180 are stacked in the up-down direction. The developing layer 180 is located above the coating layer 179.

The coating layer 179 includes a transportation space 181, a substrate transporting robot TR15, exemplarily four (plural) liquid treating units U11, and a plurality of treating units U12. The substrate transporting robot TR15 is located in the transportation space 181. The substrate transporting robot TR15 transports a substrate W among the substrate buffers BF31, BF4, the four liquid treating units U11, and the treating units U12.

As for the four liquid treating units U11, two coating units PR and two coating units BARC are used, for example (see FIGS. 22 and 24). As for the treating units U12, a cooling unit CP, a heat treating unit PAB, and an edge exposing unit EEW are used, for example (see FIG. 24).

The developing layer 180 includes a transportation space 182, a substrate transporting robot TR16, exemplarily four liquid treating units U21, and a plurality of treating units U22. The substrate transporting robot TR16 is located in the transportation space 182. The substrate transporting robot TR16 transports a substrate W among the substrate buffers BF32, BF3, the four liquid treating units U21, and the treating units U22.

As the four liquid treating units U21, four developing units DEV are used, for example (see FIGS. 22 and 23). As for the treating units U22, a cooling unit CP and a post-bake unit PB are used, for example (see FIG. 23).

### (7-4) Construction of IF Block B5

The IF block B5 is connected to the second treating block B10 horizontally. Moreover, the IF block B5 loads and unloads the substrate W into and from an external exposure device EXP. The IF block B5 in the fourth embodiment is configured in substantially the same manner as the IF block B5 shown in FIG. 1. That is, the IF block B5 includes three substrate transporting robots TR4 to TR6, a plurality of back face cleaning units BSS, a plurality of post-exposure bake treatment units PEB, a substrate platform PS9, and three mounting-cum-cooling units P-CP. Note that the IF block B5 need not provide the back face cleaning unit BSS, as necessary.

### (8) Operation of Substrate Treating Apparatus 1

The following describes the operation of the substrate treating apparatus 1 of the fourth embodiment with reference to FIGS. 21 to 24. In this description, resist coating is performed after the back polishing. The carrier C is placed on any of the four carrier platforms 173, 174. At this time, the substrate W is accommodated in the carrier C while the front face thereof is directed upwardly.

The indexer robot IR2 in the indexer block B1, for example, takes a substrate W from the carrier C placed on the carrier platform 173, and transports the taken substrate W to the substrate buffer BF31. Thereafter, the substrate transporting robot TR14 in the polishing layer 175 of the first treating block B9 takes the substrate W from the substrate buffer BF31, and transports the substrate W to the inversion unit RV41. Then, the inversion unit RV41 reverses the substrate W to change the back face of the substrate W directed upward.

Then, in the polishing layer 175, operation from the step S02 (observing scratch) to the step S05 (cleaning substrate) in the flow chart of FIG. 9 is performed. The following schematically describes the operation. The substrate transporting robot TR14 in the polishing layer 175 takes a substrate W from the inversion unit RV41, and transports the substrate W to the inspecting unit 20 and the polishing unit 22 in this order. At this time, the inspecting unit 20 detects a scratch on the back face of the substrate W and measures a depth of the scratch (step S02). Thereafter, the polishing unit 22 performs wet etching treatment on the back face of the substrate W (step S03).

Thereafter, the polishing unit 22 polishes the back face of the substrate W in a chemo-mechanical grinding (CMG) manner by contacting the polisher 96 against the rotating substrate W while the hot plate 45 heats the substrate W (step S04). Back polishing is performed in accordance with the depth of the scratch until the scratch is scraped off. Then, the polishing unit 22 cleans the back face of the substrate W (step S05). Thereafter, the substrate transporting robot TR14 takes the substrate W from the polishing unit 22, and transports the substrate W to the inversion unit RV42 and the substrate buffer BF31 in this order. At this time, the inversion unit RV42 reverses the substrate W to change the front face of the substrate W directed upward.

The substrate transporting robot TR15 in the coating layer 179 of the second treating block B10 takes the substrate W, whose back face is polished, from the substrate buffer BF31, and transports the substrate W to the cooling unit CP, the coating unit BARC, and the heat treating unit PAB in this order. Then, the substrate transporting robot TR15 takes the substrate W from the heat treating unit PAB, and transports the substrate W to the cooling unit CP, the coating unit PR, the heat treating unit PAB, the edge exposing unit EEW, and the substrate buffer BF4 in this order. At this time, the coating unit PR coats the front face of the substrate W with the resist.

The substrate transporting robot TR4 in the IF block B5, for example, takes the substrate W, coated with the resist, from the substrate buffer BF4, and transports the substrate W to the back face cleaning unit BSS and the mounting-cum-cooling unit P-CP in this order. Thereafter, the substrate transporting robot TR6 in the IF block B5 takes the substrate W from the mounting-cum-cooling unit P-CP, and unloads the substrate W to the external exposure device EXP. The exposure device EXP performs the exposure treatment on the substrate W coated with the resist. The substrate transporting robot TR6 loads the substrate W, on which the exposure treatment is performed, from the exposure device EXP, and transports the substrate W to the substrate platform PS9. Then, the substrate transporting robot TR4 transports the substrate W from the substrate platform PS9 to the post-exposure bake treatment unit PEB and the substrate buffer BF3 in this order.

In the developing layer 180 of the second treating block B10, the substrate transporting robot TR16 takes the substrate W, subjected to the exposure treatment, from the substrate buffer BF3, and transports the substrate W to the cooling unit CP, the developing unit DEV, the post-bake unit PB, and the substrate buffer BF32 in this order.

The indexer robot IR2 in the indexer block B1 takes the substrate W from the substrate buffer BF32, and returns the substrate W to the carrier C placed on the carrier platform 173.

This embodiment produces the same effect as that of the first embodiment. That is, in the substrate treating apparatus 1, the first treating block B9, the indexer block B1, and the second treating block B10 are arranged horizontally and linearly in this order. The substrate treating apparatus 1 of this type includes the polishing unit 22 (holding rotator 35, polisher 96, and hot plate 45) and the coating unit PR. The polisher 96 has a resin body in which abrasive grains are distributed. The polisher 96 polishes the back face of the substrate W in the chemo-mechanical grinding (CMG) manner by contacting against the back face of the rotating substrate W. The substrate W is heated when the polishing is performed. When the substrate W is heated, a polishing rate can increase. This can shorten time for polishing treatment.

### (9) Modification of Fourth Embodiment

The IF block B5 of the substrate treating apparatus 1 shown in FIG. 22 is horizontally connected to the second treating block B10 having the coating unit PR. In this regard, the IF block B5 may be horizontally connected to the first treating block B9 having the polishing unit 22, as shown in FIG. 25. In this case, the developing layer 180 is provided not in the second treating block B10 but in the first treating block B9. In FIG. 25, the polishing layer 175 and the developing layer 180 are stacked in the up-down direction. The developing layer 180 is located above the polishing layer 175.

An operation of the substrate treating apparatus 1 in FIG. 25 will now be described simply. In this description, back polishing is performed after the resist coating. Firstly, the substrate W is transported from the carrier C on the carrier platform 173 to the coating layer 179 in the second treating block B10. The front face of the substrate W is coated with the resist in the coating layer 179. Thereafter, the substrate W is transported to the polishing layer 175 of the first treating block B9. As shown in the flow chart of FIG. 9, the back face of the substrate W coated with the resist is polished in the polishing layer 175.

Thereafter, the substrate W is unloaded to the exposure device EXP via the IF block B5. The exposure device EXP performs the exposure treatment on the substrate W. Thereafter, the substrate W is transported to the developing layer 180 of the first treating block B9 via the IF block B5. The developing treatment is performed on the substrate W, subjected to the exposure treatment, in the developing layer 180. Thereafter, the substrate W returns back to the carrier C on the carrier platform 173.

### FIFTH EMBODIMENT

### (10) Polishing Head 201

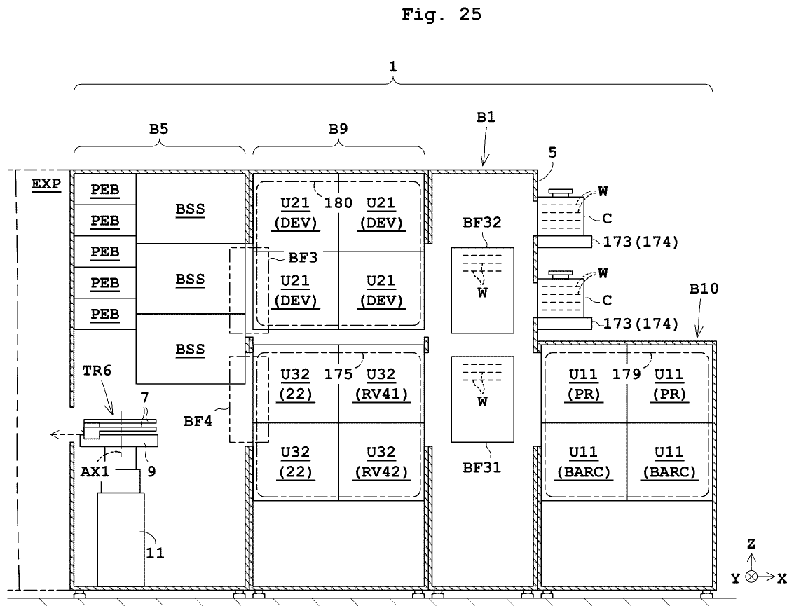

The following describes a preferred construction of the polishing mechanism 37 (fifth embodiment) mentioned above with reference to FIG. 26. FIG. 26 illustrates a preferred construction of a polishing mechanism of a polishing unit. The description common to that of the first to fourth embodiments is to be omitted.

A polishing mechanism 37A differs from the polishing mechanism 37 described above in the following construction.

A polishing head 201 is attached to an attachment member 98. The polishing head 201 includes a polisher 96.

A shaft 100 to which the attachment member 98 is attached includes inside thereof a gas supply pipe 203 and a suction pipe 205. The gas supply pipe 203 and the suction pipe 205 are arranged in parallel in the shaft 100. The gas supply pipe 203 and the suction pipe 205 are inserted into the shaft 100. The gas supply pipe 203 and the suction pipe 205 are in communication with a rotary joint 207. The rotary joint 207 has a fixing body 209 and a rotating body 211. The fixing-side body 209 is fixed to an arm 101. The rotating-side body 211 is attached to the shaft 100. The rotary joint 207 can cause at least two types of fluids to run between the fixing-side body 209 fixed to the arm 101 and the rotating-side body 211 rotating along with the shaft 100.

The gas supply pipe 203 extending from the rotary joint 207 has a first end in communication with a gas supplying source 213. The gas supplying source 213 supplies gas. The gas is preferably an inert gas. The inert gas is, for example, nitrogen gas. The gas supply pipe 203 includes a flow rate regulating valve 215 and an on-off valve 217. The flow rate regulating valve 215 regulates a flow rate of gas that flows in the gas supply pipe 203. The on-off valve 217 permits or blocks flow of the gas in the gas supply pipe 203.

The suction pipe 205 extending from the rotary joint 207 has a first end in communication with a suction source 219. The suction source 219 sucks an interior of the suction pipe 205. The suction source 219 sucks gas. The suction source 219 is, for example, a suction pump or a utility for suction provided in a clean room. The suction pipe 205 includes an on-off valve 221. The on-off valve 221 permits or blocks flow of the gas in the suction pipe 205.

The on-off valves 217 and 221 mentioned above and the flow rate regulating valve 215 are operated by the main controller 165. Here, the flow rate regulating valve 215 and the on-off valve 217 are called a control valve.

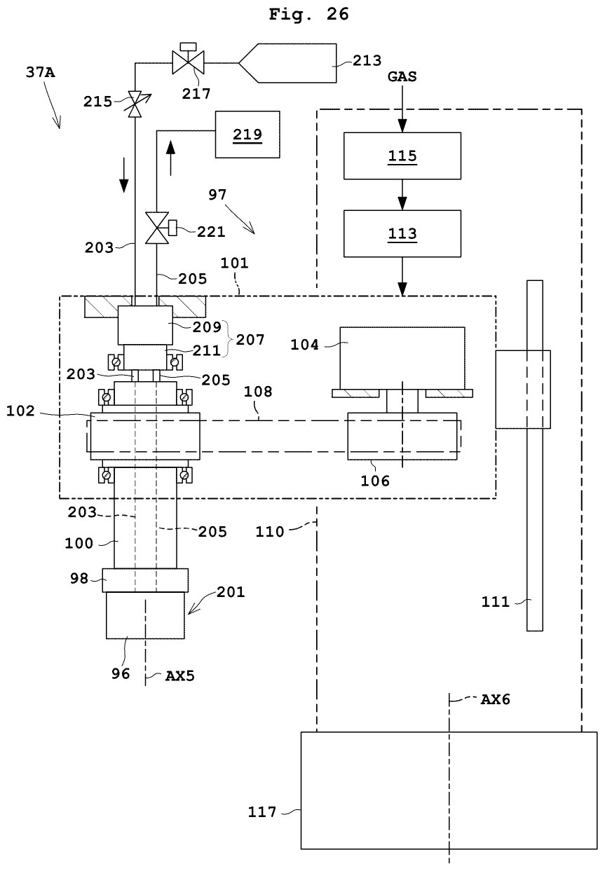

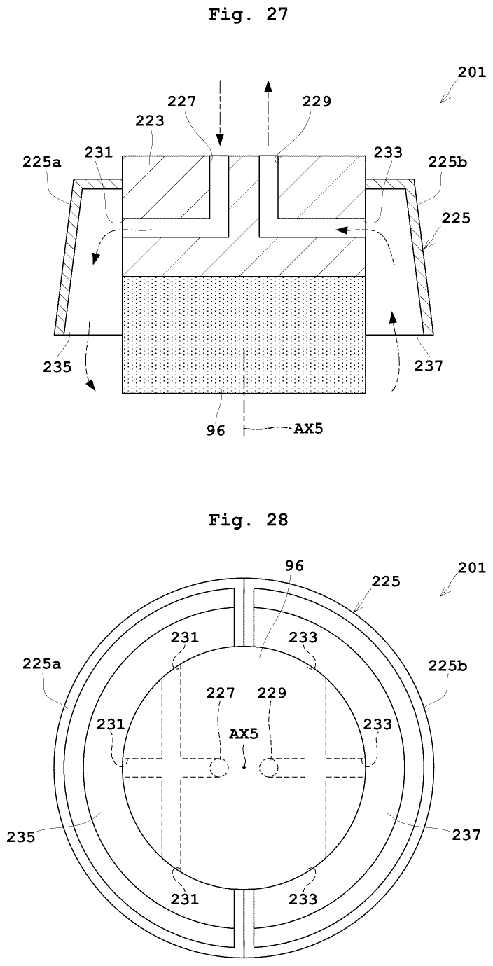

Reference is now made to FIGS. 27 and 28. FIG. 27 is a longitudinal cross-sectional view of a polishing head according to the fifth embodiment. FIG. 28 is a bottom view of the polishing head according to the fifth embodiment.

The polishing head 201 includes the polisher 96, a head body 223, and a cover 225. The polisher 96 is attached to a lower face of the head body 223. The head body 223 has a first flow path 227 and a second flow path 229 formed therein. The first flow path 227 and the second flow path 229 are not in communication with each other. The first flow path 227 and the second flow path 229 cause an upper face and an outer circumferential face of the head body 223 to communicate with each other. The first flow path 227 has three openings 231 in the outer circumferential face of the head body 223, for example. The second flow path 229 has three openings 233 in the outer circumferential face of the head body 223, for example. The first flow path 227 and the second flow path 229 are preferably formed to be axially symmetric with reference to a straight line passing the vertical axis AX5 in plan view.

The cover 225 is attached to the head body 223. The cover 225 is attached to the outer circumferential face of the head body 223. The cover 225 has a shape inclined outward from a portion extending horizontally, for example. In other words, the cover 225 has a trapezoid shape. The cover 225 has a lower end higher than a lower face of the polisher 96. This is to prevent interference between the cover 225 and the substrate W even when the polisher 96 is worn. The cover 225 includes a first cover 225a and a second cover 225b. The first cover 225a and the second cover 225b are formed to be axially symmetric with reference to the straight line passing the vertical axis AX5 in plan view.

The first cover 225a covers the opening 231 laterally. The second cover 225b covers the opening 233 laterally. A lower part of the first cover 225a forms a jet port 235. A lower part of the second cover 225b forms a suction port 237. The jet port 235 is provided along a half of the outer circumferential face of the polisher 96. The suction port 237 is provided along a half of the outer circumferential face of the polisher 96. The suction port 237 and the jet port 235 are formed to be axially symmetric with reference to the straight line passing the vertical axis AX5 in plan view.

In the polishing head 201, the first flow path 227 is in communication with a second end of the gas supply pipe 203. In the polishing head 201, the second flow path 229 is in communication with a second end of the suction pipe 205. In other words, the jet port 235 communicates with the gas supplying source 213. The suction port 237 communicates with the suction source 219.

The polishing unit 22 configured in such a manner as above polishes the substrate W as under, for example. Note that the arm 101 and the like operate as described above.

The main controller 165 performs operation concerning supply and suction of gas. Specifically, the main controller 165 sets in advance a predetermined supply flow rate of the flow rate regulating valve 215. The predetermined supply flow rate is preferably set within a range not exceeding a flow rate sucked from the suction pipe 205. The main controller 165 opens the on-off valves 217 and 221 at a timing or a slightly earlier timing of starting the polishing treatment. Thereby, nitrogen gas is supplied to the gas supply pipe 203 at a predetermined supply flow rate, and gas is sucked from the suction pipe 205.

According to this embodiment, dust particles generated at the back face of the substrate W due to polishing by the polisher 96 rotating around the vertical axis AX5 are also pushed out toward an outer circumference side of the polisher 96 by a centrifugal force. At this side, nitrogen gas is jetted from the jet port 235. Thereby, the dust particles attached to the back face of the substrate W are removed from the back face of the substrate W. The dust particles are sucked through the suction port 237. Consequently, the dust particles are hard to remain on the back face of the substrate W, achieving enhanced removal rate of dust particles caused by the polishing.

Moreover, in this embodiment, the outer circumferential face of the polisher 96 is divided axial-symmetrically in plan view, and separated parts serve as the jet port 235 and the suction port 237. This achieves a suitably maintained balance between supply and suction of the nitrogen gas at the outer circumferential face of the polisher 96. As a result, the dust particles can be removed suitably.

Moreover, with this embodiment, the flow rate of nitrogen gas from the jet port 235 is set so as not to exceed the suction flow rate. Accordingly, the dust particles are not sucked from the suction port 237 due to jetting of the nitrogen gas from the jet port 235, leading to preventing scattering around.

Moreover, it is preferred that the main controller 165 operates the flow rate regulating valve 215 to change a flow rate of nitrogen gas temporally. The flow rate in this case includes a flow rate of zero where no nitrogen gas is supplied. Thereby, a difference occurs in the flow rate of nitrogen gas jetted from the jet port 235. In other words, the nitrogen gas is supplied not constantly but discontinuously or intermittently. Moreover, the main controller 165 may operate opening and closing of the on-off valve 217 while the flow rate is made constant without operating the flow rate regulating valve 215. Thereby, the jet port 235 jets the nitrogen gas discontinuously or intermittently.

When the nitrogen gas is jetted continuously, the dust particles are pressed against the back face of the substrate W, leading to an impossibility of smooth suction or removal. Here, the main controller 165 operates the flow rate regulating valve 215 or the on-off valve 217 to make discontinuous jetting of nitrogen gas from the polishing head 201. When the nitrogen gas is jetted discontinuously or intermittently, a pressing force by the nitrogen gas is weakened temporarily. As a result, the dust particles are easily removable.

### SIXTH EMBODIMENT

The following describes a sixth embodiment of the present invention with reference to the drawings. The constructions except for a polishing head 201A are same as those described in the embodiments above.

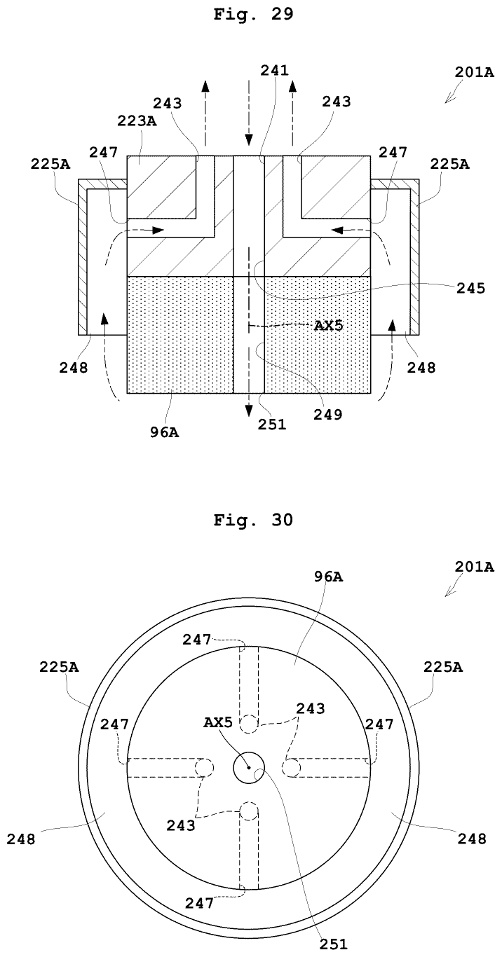

Reference is now made to FIGS. 29 and 30. FIG. 29 is a longitudinal cross-sectional view of a polishing head according to the sixth embodiment. FIG. 30 is a bottom view of the polishing head according to the sixth embodiment.

The polishing head 201A includes a polisher 96A, a head body 223A, and a cover 225A. The polisher 96A is attached to a lower face of the head body 223A. The head body 223A has a first flow path 241 and a second flow path 243 formed therein. The first flow path 241 and the second flow path 243 are not in communication with each other. The first flow path 241 has an opening 245 in a lower face of the head body 223A. The first flow path 241 substantially conforms to the vertical axis AX5. The second flow path 243 cause an upper face and an outer circumferential face of the head body 223A to communicate with each other. The second flow path 243 has four openings 247 in the outer circumferential face of the head body 223A, for example. The second flow path 243 also communicates with four openings in the upper face of the head body 223A, for example. The second flow path 243 preferably has the openings 247 whose positional relationship are equal to one another in angle in plan view: This yields uniform suction.

The cover 225A is attached to the head body 223A. The cover 225A is attached to an outer circumferential face of the head body 223A. The cover 225A has a shape suspended downward from a portion extending horizontally, for example. The cover 225A has a lower end higher than a lower face of the polisher 96A. A lower part of the cover 225A forms a suction port 248.

A through hole 249 is formed in the center of the polisher 96A. The polisher 96A is annular in plan view: The through hole 249 substantially overlaps the vertical axis AX5 in plan view. The through hole 249 overlaps the first flow path 241 in plan view: The through hole 249 communicates with the first flow path 241. An opening of the through hole 249 communicating with the lower face of the polisher 96A corresponds to a jet port 251.

In the polishing head 201A, the first flow path 241 is in communication with a second end of a gas supply pipe 203. In the polishing head 201A, the second flow path 243 is in communication with a second end of a suction pipe 205. In other words, the jet port 251 communicates with a gas supplying source 213. The suction port 248 communicates with a suction source 219.

According to this embodiment, nitrogen gas jetted from the center of the polisher 96A runs over the back face of the substrate W toward the outer periphery of the polisher 96A. This can achieve efficient suction of the nitrogen gas, containing the dust particles, through the suction port 248.

### SEVENTH EMBODIMENT

The following describes a seventh embodiment of the present invention with reference to the drawings. The constructions except for a polishing head 201B are same as those described in the embodiments above.

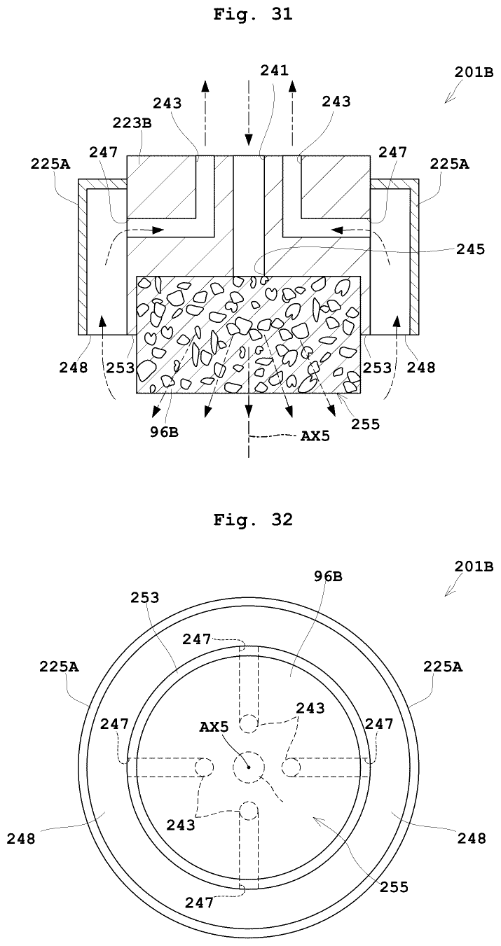

Reference is now made to FIGS. 31 and 32. FIG. 31 is a longitudinal cross-sectional view of a polishing head according to the seventh embodiment. FIG. 32 is a bottom view of the polishing head according to the seventh embodiment.

A polishing head 201B includes a polisher 96B, a head body 223B, and a cover 225A. The polisher 96B is attached to a lower face of the head body 223B. The head body 223B has a first flow path 241 and a second flow path 243 formed therein. The first flow path 241 and the second flow path 243 are same as those described in the sixth embodiment. An edge 253 is formed in the head body 223B. The edge 253 is formed by an edge portion of a lower face of the head body 223B protruding downward. The polishing member 96B is attached to the edge 253.

The polisher 96B is formed by a porous member. Many fine holes are formed in the polisher 96B. Many fine holes of the polisher 96B are in communication with one another. Nitrogen gas supplied from the first flow path 241 is jetted from the lower face of the polisher 96B to the back face of the substrate W through many fine holes of the polisher 96B. In other words, the lower face of the polisher 96B constitutes a jet port 255.

The cover 225A is configured in the same manner as that in the sixth embodiment described above, and has a suction port 248 formed in its lower part.

According to this embodiment, nitrogen gas is supplied to the polisher 96B made of the porous member, and the nitrogen gas can be jetted to dust particles from the jet port 255 corresponding to substantially the entire of the lower face of the polisher 96B. As a result, dust particles can be pushed out efficiently to an outer periphery.

### Eighth Embodiment

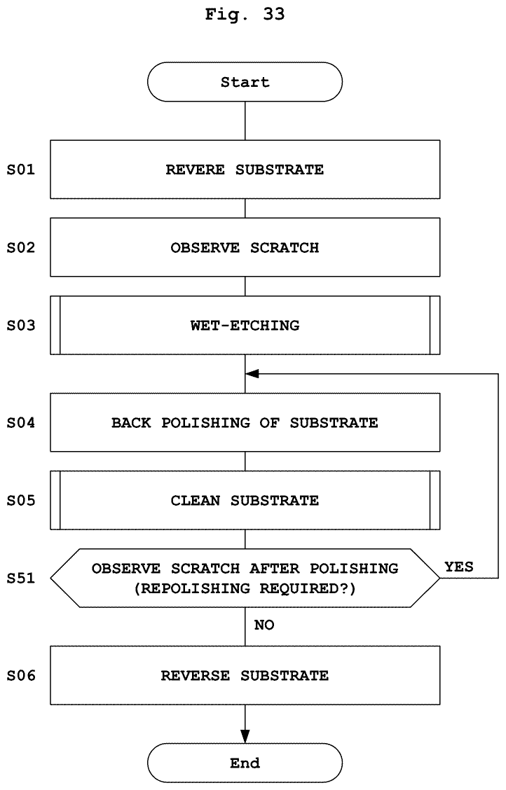

The following describes an eighth embodiment of the present invention with reference to drawings. Here, the description common to those of the first to seventh embodiments is to be omitted. FIG. 33 is a flow chart illustrating operation of a polishing treatment device according to the eighth embodiment.

In the first embodiment, scratch observation is not performed after a back face of a substrate W is polished (step S04). In this regard, scratch observation is performed after a back face of a substrate W is polished (step S51 in FIG. 33) in the eighth embodiment.

Here, operation substantially same as that in the steps S01 to S06 shown in FIG. 9 is performed in the steps S01 to S06 shown in FIG. 33, respectively. After a cleaning step of a substrate W (step S05), a substrate transporting robot TR1 takes the substrate W from a polishing unit 22, and transports the substrate W to a stage 121 of one of two inspecting units 20.

[Step S51] Observing Scratch after Polishing

The inspecting unit 20 especially detects the scratch formed on the back face of the substrate W again. That is, similarly to the operation of step S02, the inspecting unit 20 acquires an observed image by a camera 124 and a lighting portion 125. An inspection controller 130 extracts a scratch to be polished by performing image processing to the acquired observed image. When a scratch to be polished is not extracted, the main controller 165 determines that repolishing is unnecessary, and the procedure proceeds to the step S06.

In contrast to this, when a scratch to be polished is extracted, the main controller 165 determines that repolishing is necessary. Then, the inspecting unit 20 measures a depth of the scratch to be polished. That is, a laser microscope 127 captures a three-dimensional image containing the scratch to be polished. The inspection controller 130 measures a depth of the scratch to be polished (value DP3 in FIG. 10(b)) by performing image processing to the obtained three-dimensional image.

Thereafter, the substrate transporting robot CR transports the substrate W from the stage 121 of the inspecting unit 20 to a holding rotator 35 of the polishing unit 22. After the transportation, the substrate W is held by the holding rotator 35, and gas is ejected from a gas ejection port 47. Then, a substrate thickness measuring device 39 is moved above the substrate W, and measures a thickness of the substrate W (value TK3 in FIG. 10(b)). The procedure returns to the step S04.

In the step S04, the polishing unit 22 again polishes the back face of the substrate W when the inspecting unit 20 extracts a scratch to be polished. Polishing is performed until the thickness (value DP3) corresponding to the depth of the scratch is scraped off. In other words, polishing is performed until the thickness of the substrate W is brought into a value TK2 (=TK3−DP3) shown in FIG. 10(b).

According to this embodiment, since polishing is performed until a scratch to be polished that needs polishing is eliminated, a new damage on a stage of an exposure device EXP, for example, caused by the edge of the scratch may be prevented.

Moreover, when a scratch to be polished is present in this embodiment, a wet-etching step (step S03) is not performed before the back face is polished again. In this regard, the wet-etching may be performed, as necessary.

### NINTH EMBODIMENT

The following describes a ninth embodiment of the present invention with reference to drawings. Here, the description common to that of the first to eighth embodiments is to be omitted.

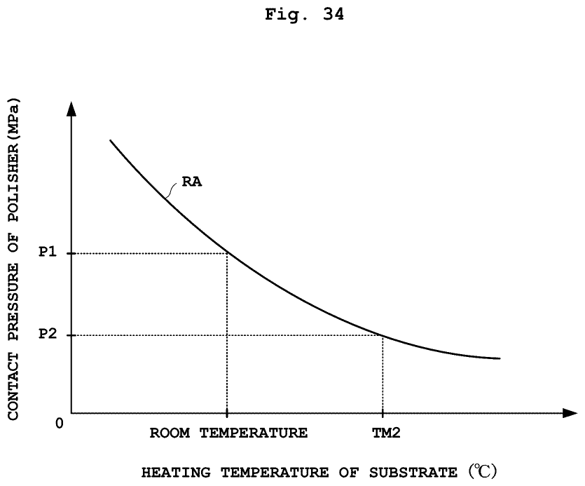

FIG. 34 illustrates a relationship between a heating temperature of a substrate W and a contact pressure (pushing pressure) of a polisher 96. FIG. 34 is a view where the polishing rate is made constant. In FIG. 34, it is assumed that a given polishing rate RA is obtained when the substrate W has a temperature of room temperature (e.g., 25° C.) and given contact pressure P1. When the substrate W is heated, the polishing rate increases. Accordingly, a contact pressure P2 lower than the contact pressure P1 is obtainable when the temperature is made higher than room temperature (e.g., temperature TM2) while the polishing rate RA is maintained. That is, if the polishing rate RA is constant, the contact pressure can be lowered by raising the temperature of the substrate W.

With this embodiment, the polishing unit 22 can adjust the polishing rate by controlling the contact pressure of the polisher 96 against the substrate W in addition to the heating temperature of the substrate W. For example, raising the heating temperature of the substrate W while keeping the polishing rate allows decreased contact pressure of the polisher 96 against the substrate W. This can suppress load of the substrate W caused by the contact pressure. That is, excess pushing against a substrate W can be prevented.

Here, adjustment of the polishing rate is not limitedly performed from a relationship between the heating temperature of the substrate W and the contact pressure of the polisher 96. That is, adjustment of the polishing rate may be performed with use of a relationship between the heating temperature of the substrate W and a moving speed of the polisher 96. Moreover, adjustment of the polishing rate may be performed with use of a relationship between the heating temperature of the substrate W and a moving speed of the polisher 96 around a vertical axis AX6 (swinging speed). Adjustment of the polishing rate may be performed with use of a relationship between the heating temperature of the substrate W and a rotation speed of the polisher 96 around a vertical axis AX5. Adjustment of the polishing rate may be performed with use of a relationship between the heating temperature of the substrate W and a rotation speed of the substrate W.

That is, the polishing unit 22 may adjust the polishing rate by controlling at least one selected from the contact pressure of the polisher 96 against the substrate W, the moving speed of the polisher 96, the rotation speed of the polisher 96, and the rotation speed of the substrate W in addition to the heating temperature of the substrate W.

### TENTH EMBODIMENT

The following describes a tenth embodiment of the present invention with reference to drawings. Here, the description common to that of the first to ninth embodiments is to be omitted.

In FIG. 1, the treating unit U1 corresponds to the inspecting unit 20 and each of the treating units U2 to U4 corresponds to a polishing unit 22 in the first embodiment. In the tenth embodiment, each of treating units U2 and U3 may correspond to a polishing unit 341, and the treating unit U4 may correspond to a liquid treating unit 343. Here, a treating unit U1 corresponds to an inspecting unit 20.

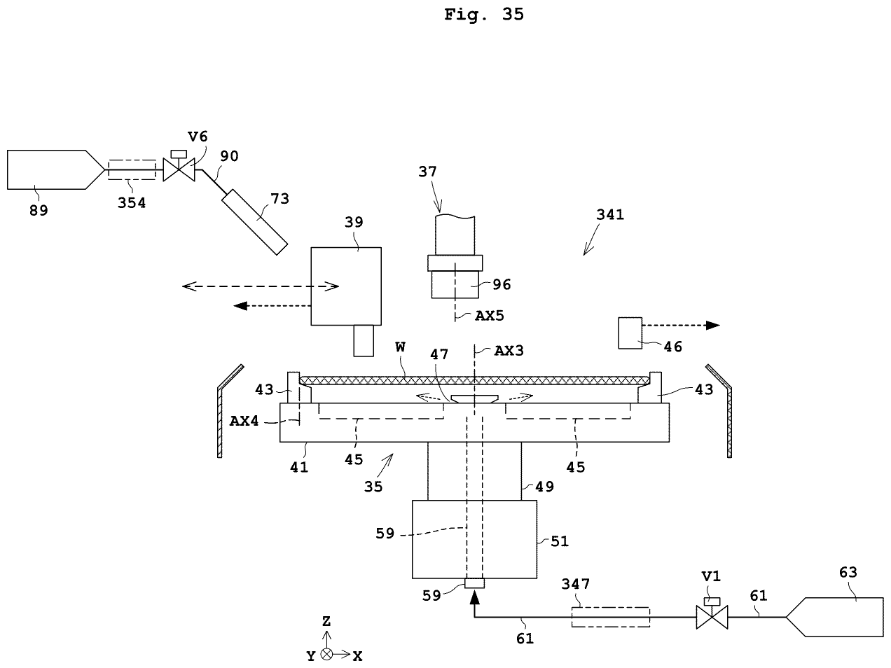

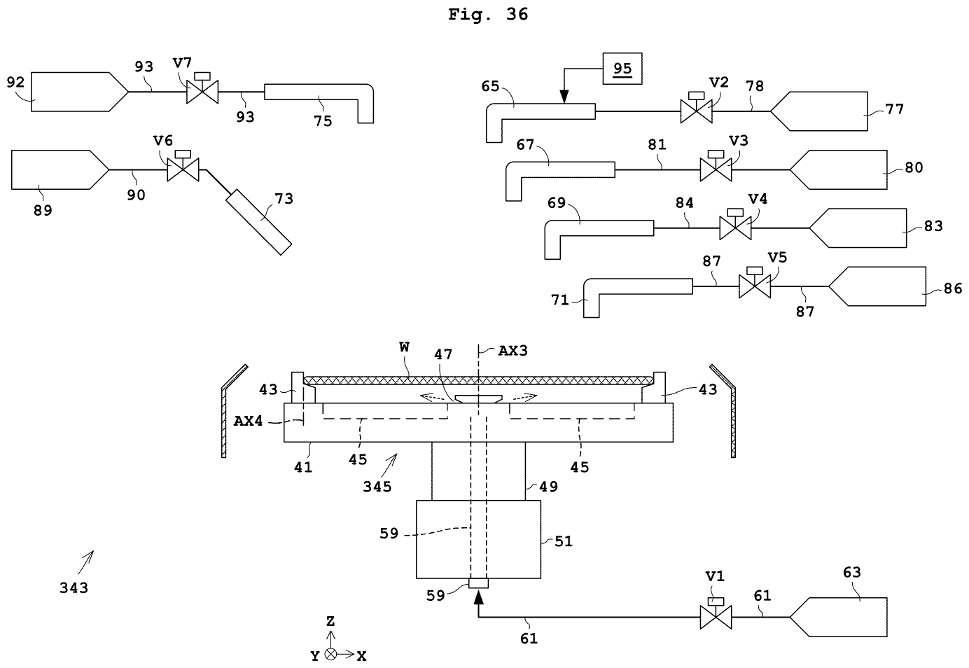

That is, the polishing layers 14A, 14B in the tenth embodiment include a two-stage inspecting unit 20, two by two stages of polishing units 341, and a two-stage liquid treating unit 343. In other words, the polishing layers 14A, 14B each include eight treating units U1 to U4. FIG. 35 illustrates the polishing unit 341 according to the tenth embodiment. FIG. 36 illustrates the liquid treating unit 343 according to the tenth embodiment.

The polishing unit 341 and the liquid treating unit 343 are formed by dividing the polishing unit 22 in FIG. 4 into two, for example. Here, the liquid treating unit 343 includes a second holding rotator 345 that is configured in the same manner as the holding rotator 35. Moreover, the polishing unit 341 may include a rinse liquid nozzle 73, a rinse liquid supplying source 89, and a rinse liquid pipe 90.

Operation in the polishing layers 14A, 14B is performed in accordance with the flow chart shown in FIG. 9 or FIG. 33. However, the substrate W is transported between the polishing unit 341 and the liquid treating unit 343, for example. In the steps S02 to S05 in FIG. 9, for example, the substrate W is transported by a substrate transporting robot TR1 to the inspecting unit 20, the liquid treating unit 343 (wet-etching step), the polishing unit 341, and the liquid treating unit 343 (cleaning step of the substrate W) in this order.

This embodiment produces the same effect as that of the first embodiment. Moreover, the polishing unit 341 and the liquid treating unit 343 can each be made compact since they are formed by dividing the polishing unit 22 in FIG. 4 into two, for example.

Here, the polishing unit 341 may be provided with a construction concerning the wet-etching step (step S03) in the liquid treating unit 343. Moreover, the polishing unit 341 may be provided with a construction concerning the cleaning step (step S05) of the substrate W in the liquid treating unit 343. Moreover, in the tenth embodiment, the polishing unit 341 does not include heaters 347, 354 (see FIG. 35) mentioned later.

The present invention is not limited to the foregoing examples, but may be modified as follows.

(1) In the embodiments described above, suction is performed from the suction ports 237 and 248 with large openings provided in the covers 225 and 225A, respectively. However, the present invention is not limited to this configuration. For example, such a pipe configuration may be adopted that a first end of the pipe communicates with the openings 233 and 247 of the head body 223 (223A, 223B) and a second end of the pipe faces a polishing face.

(2) In each of the embodiments described above, nitrogen gas is jetted from the jet port. However, gas is not limited to nitrogen gas in the present invention. For example, argon gas may be used as the gas.

(3) In each of the embodiments described above, the gas supply pipe 203 and the suction pipe 205 are arranged in parallel. However, the present invention is not limited to this construction. For example, such a construction may be adopted that a jacketed pipe is inserted into the shaft 100 for gas supply and suction.

(4) In each of the embodiments described above, the main controller 165 operates the flow rate regulating valve 215 to change a flow rate of the nitrogen gas temporally. However, such operation is not essential in the present invention. That is, the flow rate of the nitrogen gas may be kept constant during the polishing treatment.

(5) In each of the embodiments described above, the polishing heads 201, 201A, and 201B are removably attached to the attachment member 98. However, such is adoptable that the polishing heads 201, 201A, and 201B are semi-fixed to the attachment member 98 and only the polishers 96, 96A, 96B are attachable and detachable, and thus easily replaceable.

(6) In each of the embodiments and the modifications described above, the polishing unit 22 includes the hot plate 45 as the heating member. Instead of the hot plate 45, the polishing unit 22 may be configured such that the gas ejection port 47 ejects heated gas. Heated gas from the gas ejection port 47 can heat the substrate. In this case, the polishing unit 22 may include a heater 347 (see FIGS. 4 and 35) for heating gas, passing through the gas pipe 61, from outside of the gas pipe 61, for example. In this case, the polishing unit 22 does not necessarily include the hot plate 45. Moreover, the substrate W may be heated by both the hot plate 45 and the heated gas ejected from the gas ejection port 47. The gas ejection port 47 corresponds to the heating member in the present invention.

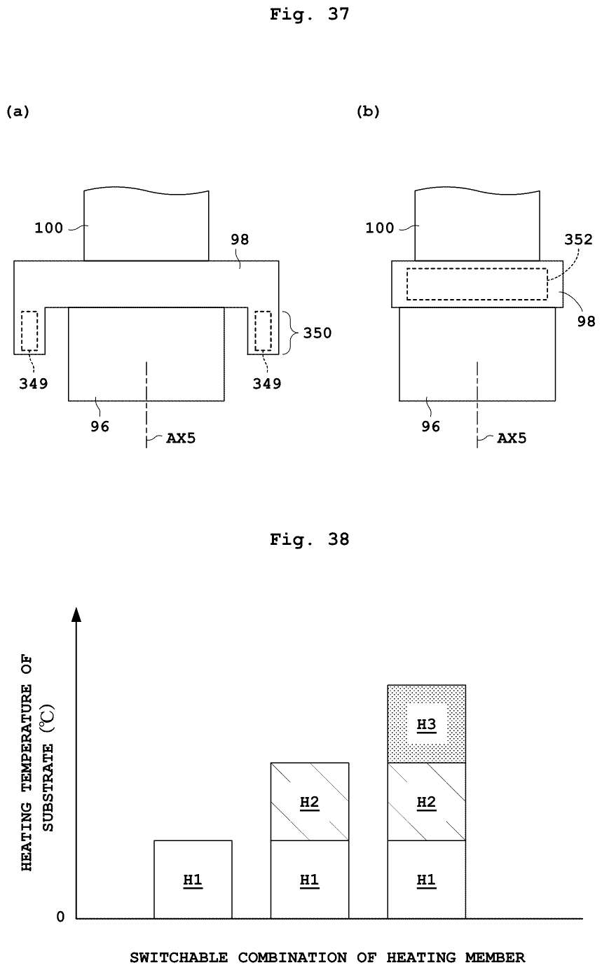

(7) In each of the embodiments and the modifications described above, the polishing unit 22 includes the hot plate 45 as the heating member. In this regard, as shown in FIGS. 37(a) and 37(b), the polishing unit 22 may include a heater 349 (352), instead of the hot plate 45, for heating the polisher 96. Alternatively, the polishing unit 22 may include the hot plate 45 and the heater 349 (352). In FIG. 37(a), an attachment member 98 is configured like a vessel whose lower face is recessed. The heater 349 in a ring shape is provided on a hollow tubular portion 350 of the attachment member 98 surrounding the polisher 96 (vertical axis AX5). The heater 349 heats the polisher 96. When the polisher 96 is heated, the substrate W can be heated via the polisher 96. Moreover, an interface between the polisher 96 and the back face of the substrate W can be heated effectively.

Moreover, as shown in FIG. 37(b), the heater 352 may be embedded in the attachment member 98 and arranged between the shaft 100 and the polisher 96. Here, the heaters 349 and 352 may each perform heating with an electric heater such as a nichrome wire, for example. Moreover, the heaters 349 and 352 may each include a pipe and perform heating by supplying heated gas or a heated liquid through the pipe. The heaters 349 and 352 each correspond to the heating member in the present invention.

(8) In each of the embodiments (except the fifth to seventh embodiments) and the modifications described above, the back face of the substrate W is polished with the polisher 96 in the dry chemo-mechanical grinding manner. In this regard, the polisher 96 may polish the back face of the substrate W in the chemo-mechanical grinding manner by supplying a liquid over the back face of the substrate W. For example, the rinse liquid nozzle 73 (FIGS. 4 and 35) may supply heated pure water (e.g., DIW) over the back face of the substrate W and in the vicinity of the polisher 96. Heated pure water can heat the substrate W. Moreover, heated pure water can wash off the polishing scraps from the back face of the substrate W. For example, the polishing unit 22 (341) may include a heater 354 for heating pure water, passing through the rinse liquid pipe 90, from outside of the rinse liquid pipe 90. Moreover, the substrate W may be heated by the heated pure water from the rinse liquid nozzle 73 without being heated by the hot plate 45. In this case, the polishing unit 22 does not necessarily include the hot plate 45. Here, the rinse liquid nozzle 73 corresponds to the heating member in the present invention.

Moreover, the substrate W may be heated by at least one selected from the hot plate 45, the gas ejection port 47 that ejects heated gas, the heater 349 (or heater 352) for heating the polisher 96, and the rinse liquid nozzle 73 for supplying the heated pure water to the back face of the substrate W.

Moreover, the polishing unit 22 may include these heating members, and may combine the heating members for controlling the heating temperature of the substrate W. For example, it is assumed that heating is performed only by the hot plate 45 (numeral H1 in FIG. 38). When more heating is required, the substrate W may be heated by the gas ejection port 47, in addition to the hot plate 45, that ejects heated gas (numeral H1 and numeral H2 in FIG. 38). Moreover, when further heating is required, the substrate W may be heated by the heater 349 (or heater 352), in addition to the hot plate 45 and the gas ejection port 47, that heats the polisher 96 (numeral H1, numeral H2, and numeral H3 in FIG. 38). When heating needs to be suppressed from this state, the substrate W may be heated only by the hot plate 45 (numeral H1).

(9) In each of the embodiments and the modifications described above, the substrate thickness measuring device 39 measures the thickness of the substrate W prior to the wet-etching step (step S03). In this regard, the substrate thickness measuring device 39 may measure the thickness of the substrate W between the wet-etching step (step S03) and the back polishing step (step S04) of the substrate W. In this case, the scratch observing step (step S02) may be shifted between the steps S03 and S04.

(10) In each of the embodiments and modifications described above, the contact pressure of the polisher 96 against the substrate W may be detected by a load cell, for example. Moreover, the moving speed of the polisher 96 may be detected by a rotary encoder that detects an angle of the polisher 96 around the vertical axis AX6. Moreover, the rotation speed of the polisher 96 may be detected by a rotary encoder that detects an angle of the polisher 96 around the vertical axis AX5. Moreover, the rotation speed of the substrate W may be detected by a rotary encoder that detects an angle of the substrate W around the rotary axis AX3. The main controller 165 may control each component based on these detected results.

(11) In each of the embodiments and the modifications described above, the holding rotator 35 holds the substrate W, whose back face is directed upward, in a horizontal posture. Moreover, the spin base 41 of the holding rotator 35 is located below the substrate W. In this regard, the holding rotator 35 may be arranged upside down. That is, the spin base 41 of the holding rotator 35 is located above the substrate W (see the holding rotator 157 in FIG. 3). Moreover, the holding rotator 35 holds the substrate W, whose back face is directed downward, in a horizontal posture. In this case, the polisher 96 is brought into contact against the substrate W whose back face is directed downward from a side below the substrate W.

(12) In each of the embodiments and the modifications described above, the steps S21 to S26 are performed as the wet-etching step (FIG. 11). Among the six steps S21 to S26, only the steps S21 to S23 may be performed. Alternatively, among the six steps S21 to S26, only the steps S24 to S26 may be performed.

(13) In each of the embodiments and the modifications described above, the steps S31 to S36 are performed as the cleaning step of the substrate W (FIG. 13). Among the six steps S31 to S36, only the steps S31 to S33 may be performed. Alternatively, among the six steps S31 to S36, only the steps S34 to S36 may be performed.

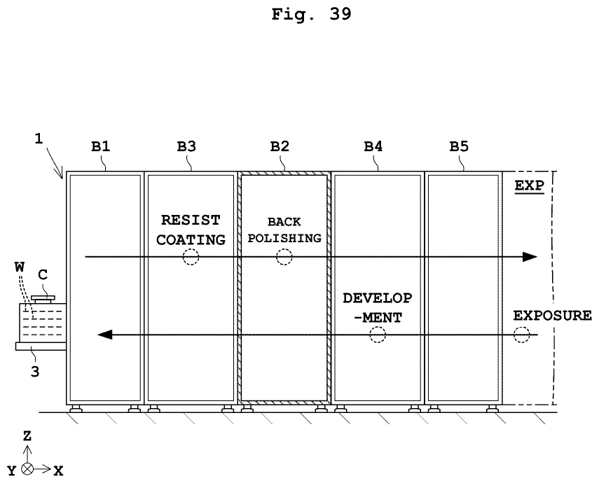

(14) In the substrate treating apparatus 1 according to the first embodiment described above, the indexer block B1, the polishing block B2, the coating block B3, the developing block B4, and the IF block B5 are arranged horizontally in this order. Moreover, after the back face is polished in the polishing block B2, the front face of the substrate W is coated with the resist in the coating block B3. Regarding to this, the indexer block B1, the coating block B3, the polishing block B2, the developing block B4, and the IF block B5 may be arranged horizontally and linearly in this order, as shown in FIG. 39. Moreover, the back face of the substrate W may be polished in the polishing block B2 after the resist is applied in the coating block B3.

(15) In each of the embodiments and the modifications described above, the exposure device EXP includes the light source for emitting the EUV rays. The light source may emit rays having a wavelength different from that of the EUV rays (e.g., ArF ray (193 nm) and KrF ray (248 nm)).

### REFERENCE SIGNS LIST

1 . . . substrate treating apparatus
B1 . . . indexer block
B2 . . . polishing block
B3 . . . coating block
B4 . . . developing block
B5 . . . interface block (IF block)
B7 . . . intermediate block
B8 . . . treating block
B9 . . . first treating block
B10 . . . second treating block
3, 173, 174 . . . carrier platform
IR1 to IR3 . . . indexer robot
TR1 to TR16 . . . substrate transporting robot
U1 to U4, U31, U32 . . . treating unit
U11, U12, U21, U22 . . . treating unit
20 . . . inspecting unit
22, 341 . . . polishing unit
35 . . . holding rotator
41 . . . spin base
43 . . . holding pin
45 . . . hot plate
47 . . . gas ejection port
73 . . . rinse liquid nozzle
96 . . . polisher
127 . . . laser scanning confocal microscope (laser microscope)
PR . . . coating unit
L1, L2 . . . coating layer
L3, L4 . . . polishing layer
L5, L6 . . . developing layer
G1 . . . buffer group
BF11, BF13 to BF16, BF21, BF22 . . . substrate buffer
347, 349, 352, 354 . . . heater

1. A substrate treating apparatus, comprising:
an indexer block which is provided with a carrier platform configured to place thereon a carrier that accommodates a substrate and in which the substrate is loaded and unloaded to and from the carrier placed on the carrier platform;
a treating block in which predetermined treatment is performed on the substrate; and
an interface block in which the substrate is loaded and unloaded to and from an external exposure device,
the indexer block, the treating block, and the interface block being arranged horizontally and linearly in this order,
the treating block including a coating block and a polishing block that are arranged horizontally and linearly,
the coating block including a coating unit configured to coat a front face of the substrate with a resist,
the polishing block including a polishing unit configured to polish a back face of the substrate, and
the polishing unit including:
a holding rotator configured to rotate the substrate while holding the substrate in a horizontal posture;
a heating member configured to heat the substrate; and
a polisher having a resin body where abrasive grains are distributed and configured to polish the back face of the substrate in a chemo-mechanical grinding manner by contacting against the back face of the substrate that is rotated while being heated.

2. The substrate treating apparatus according to claim 1, further comprising:
a controller, wherein
the controller adjusts a polishing rate by controlling a heating temperature of the substrate with the heating member when polishing is performed.

3. The substrate treating apparatus according to claim 2, wherein
the controller adjusts the polishing rate by also controlling at least one selected from a contact pressure of the polisher against the substrate, a moving speed of the polisher, a rotation speed of the polisher, and a rotation speed of the substrate.

4. The substrate treating apparatus according to claim 1, wherein
the holding rotator includes a spin base that is rotatable around a rotary axis extending in an up-down direction, and
three or more holding pins that are provided on a top face of the spin base so as to surround the rotary axis in a ring shape, and configured to hold the substrate by sandwiching a side face of the substrate so that the substrate is held apart from the top face of the spin base, and
the heating member is a first heater provided on the top face of the spin base.

5. The substrate treating apparatus according to claim 1, wherein
the holding rotator includes a spin base that is rotatable around a rotary axis extending in an up-down direction, and
three or more holding pins that are provided on a top face of the spin base so as to surround the rotary axis in a ring shape, and configured to hold the substrate by sandwiching a side face of the substrate so that the substrate is held apart from the top face of the spin base, and
the heating member is a gas ejection port that is opened in the top face of the spin base and provided in a center portion of the spin base, and configured to eject heated gas in such a manner that the gas flows in a gap between the substrate and the spin base from a portion adjacent to the center of the substrate to an outer edge of the substrate.

6. The substrate treating apparatus according to claim 1, wherein
the heating member is a second heater for heating the polisher.

7. The substrate treating apparatus according to claim 1, wherein
the heating member is a heated water supply nozzle for supplying heated water to the back face of the substrate.

8. The substrate treating apparatus according to claim 1, wherein
the treating block further includes a developing block in which developing treatment is performed on the substrate subjected to exposure treatment by the exposure device, and
the coating block, the polishing block, and the developing block are arranged horizontally and linearly.

9. A substrate treating apparatus, comprising:
an indexer block which is provided with a carrier platform configured to place thereon a carrier that accommodates a substrate and in which the substrate is loaded and unloaded to and from the carrier placed on the carrier platform;
a treating block in which predetermined treatment is performed on the substrate; and
an interface block in which the substrate is loaded and unloaded to and from an external exposure device,
the indexer block, the treating block, and the interface block being arranged horizontally and linearly in this order,
the treating block including a coating unit configured to coat a front face of the substrate with a resist,
the interface block including a polishing unit configured to polish a back face of the substrate coated with the resist by the coating unit, and
the polishing unit including:
a holding rotator configured to rotate the substrate while holding the substrate in a horizontal posture;
a heating member configured to heat the substrate; and
a polisher having a resin body where abrasive grains are distributed and configured to polish the back face of the substrate in a chemo-mechanical grinding manner by contacting against the back face of the substrate that is rotated while being heated.

10. The substrate treating apparatus according to claim 9, wherein
the treating block includes a coating block and a developing block,
the coating block includes the coating unit,
the developing block includes a developing unit configured to perform developing treatment on the substrate subjected to exposure treatment by the exposure device, and
the developing block is arranged between the coating block and the interface block.

11. A substrate treating apparatus, comprising:
an indexer block which is provided with a carrier platform configured to place thereon a carrier that accommodates a substrate and in which the substrate is loaded and unloaded to and from the carrier placed on the carrier platform;
a treating block in which predetermined treatment is performed on the substrate; and
an interface block in which the substrate is loaded and unloaded to and from an external exposure device,
the indexer block, the treating block, and the interface block being arranged horizontally and linearly in this order,
the treating block includes a coating layer and a polishing layer laminated in an up-down direction,
the coating layer including a coating unit configured to coat a front face of the substrate with a resist,
the polishing layer including a polishing unit configured to polish a back face of the substrate, and
the polishing unit including:
a holding rotator configured to rotate the substrate while holding the substrate in a horizontal posture;
a heating member configured to heat the substrate; and
a polisher having a resin body where abrasive grains are distributed and configured to polish the back face of the substrate in a chemo-mechanical grinding manner by contacting against the back face of the substrate that is rotated while being heated.

12. The substrate treating apparatus according to claim 11, wherein
the treating block further includes a developing layer where developing treatment is performed on the substrate subjected to exposure treatment by the exposure device, and
the developing layer, the coating layer, and the polishing layer are stacked in the up-down direction.

13. The substrate treating apparatus according to claim 11, further comprising:
an intermediate block arranged between the indexer block and the treating block, wherein
the intermediate block includes a buffer group and a substrate transporting robot,
the buffer group including a plurality of substrate buffers arranged in the up-down direction and on each of which the substrate is placed,
the substrate transporting robot transports the substrate among the plurality of substrate buffers, and
the indexer block transports the substrate to and from the treating block via the buffer group.

14. A substrate treating apparatus, comprising:
a first treating block provided with a polishing unit configured to polish a back face of a substrate;
an indexer block which is provided with a carrier platform configured to place thereon a carrier that accommodates a substrate and in which the substrate is loaded and unloaded to and from the carrier placed on the carrier platform;
a second treating block provided with a coating unit configured to coat a front face of the substrate with a resist; and
an interface block which is coupled to the first treating block or the second treating block horizontally and in which the substrate is loaded and unloaded to and from an external exposure device,
the first treating block, the indexer block, and the second treating block being arranged horizontally and linearly in this order, and
the polishing unit including:
a holding rotator configured to rotate the substrate while holding the substrate in a horizontal posture;
a heating member configured to heat the substrate; and
a polisher having a resin body where abrasive grains are distributed and configured to polish the back face of the substrate in a chemo-mechanical grinding manner by contacting against the back face of the substrate that is rotated while being heated.

15. The substrate treating apparatus according to claim 14, wherein
the second treating block further includes a developing unit where developing treatment is performed on the substrate subjected to exposure treatment by the exposure device, and
the interface block is coupled to the second treating block horizontally.
